(19) United States
(12) Patent Application Publication
(10) Pub. No.: US 2025/0056980 A1
(43) Pub. Date: Feb. 13, 2025

(54) Display Panel and Preparation Method Therefor, and Display Device

(71) Applicants: MIANYANG BOE OPTOELECTRONICS TECHNOLOGY CO.,Ltd., Mianyang, Sichuan (CN); BOE Technology Group Co., Ltd., Beijing (CN)

(72) Inventors: Yongkai WU, Beijing (CN); Bo ZHANG, Beijing (CN); Zhengping XIONG, Beijing (CN); Yunzhi WANG, Beijing (CN); Haoyuan FAN, Beijing (CN); Jinyu CHAO, Beijing (CN); Yixiang YANG, Beijing (CN); Gaoyun WANG, Beijing (CN); Chao LIU, Beijing (CN)

(21) Appl. No.: 18/291,237

(22) PCT Filed: Sep. 21, 2022
(86) PCT No.: PCT/CN2022/120308

§ 371 Date: Jan. 23, 2024

(51) Int. Cl. H10K 59/126; H10K 59/131; H10K 59/80

(52) U.S. Cl. CPC H10K 59/126; H10K 59/1315; H10K 59/8793

(57) ABSTRACT

The display panel comprises a display region and a bonding region, the bonding region comprises a display substrate and a first adhesive layer, a polarizing layer, a second adhesive layer and a cover plate layer arranged sequentially on a light exit side of the display substrate, the first adhesive layer and the polarizing layer are disposed in a lead region, a bending region and a composite circuit region in the bonding region, the cover plate layer is provided with a cover plate shield layer, at least one of the display substrate, the first adhesive layer and the polarizing layer is provided with a bonding shield layer, the distance between an edge of the bonding shield layer and the boundary of the display region is less than the distance between an edge of the cover plate shield layer and the boundary of the display region.

### CROSS-REFERENCE TO RELATED APPLICATIONS

The present application is a U.S. National Phase Entry of International Application PCT/CN2022/120308 having an international filing date of Sep. 21, 2022, and the contents disclosed in the above-mentioned application are hereby incorporated as a part of this application.

### TECHNICAL FIELD

The present disclosure relates, but is not limited, to the technical field of display, and particularly to a display panel, a preparation method thereof, and a display device.

### BACKGROUND

An Organic Light Emitting Diode (OLED) and a Quantum dot Light Emitting Diode (QLED) are active light emitting display devices and have advantages such as self-luminescence, a wide viewing angle, a high contrast ratio, low power consumption, an extremely high response speed, lightness and thinness, flexibility, and a low cost. With constant development of display technologies, a display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In one aspect, an exemplary embodiment of the present disclosure provides a display panel including a display region and a bonding region located on a side of the display region, the bonding region includes a lead region, a bending region and a composite circuit region arranged sequentially in a direction away from the display region, the bending region is configured to flip the composite circuit region to a back of the display region by being bent; in a plane perpendicular to the display panel, the bonding region includes a display substrate, a first functional layer on a light exit side surface of the display substrate, and a second functional layer on a backlight side surface of the display substrate, the first functional layer at least includes a first adhesive layer, a polarizing layer disposed on a side of the first adhesive layer away from the display substrate, a second adhesive layer disposed on a side of the polarizing layer away from the display substrate, and a cover plate layer disposed on a side of the second adhesive layer away from the display substrate; the first adhesive layer and the polarizing layer are arranged in the lead region, the bending region and the composite circuit region, a side of the cover plate layer close to the display substrate is provided with a cover plate shield layer, and at least one of the display substrate, the first adhesive layer and the polarizing layer is provided with a bonding shield layer, the distance between an edge of a side of the bonding shield layer close to the display region and the boundary of the display region is less than the distance between an edge of a side of the cover plate shield layer close to the display region and the boundary of the display region, and the boundary of the display region is an edge of a side of the display region close to the bonding region.

In an exemplary implementation mode, the bonding shield layer includes a first shield layer disposed in the display substrate, the distance between an edge of a side of the first shield layer close to the display region and the boundary of the display region is less than or equal to 10 μm, and an orthographic projection of the first shield layer on a plane of the display substrate at least partially overlaps an orthographic projection of the cover plate shield layer on the plane of the display substrate.

In an exemplary implementation mode, in a plane perpendicular to the display panel, the display substrate includes a drive circuit layer disposed on a base substrate, a light emitting structure layer disposed on a side of the drive circuit layer away from the base substrate, an encapsulation structure layer disposed on a side of the light emitting structure layer away from the base substrate, and a touch structure layer disposed on a side of the encapsulation structure layer away from the base substrate, the first shield layer is disposed in the touch structure layer.

In an exemplary implementation mode, the material of the first shield layer comprises a black-doped organic material and is prepared and formed by a patterning process with mask exposure accuracy less than 1 μm.

In an exemplary implementation mode, the first shield layer has a width of 350 to 450 μm, the width is a dimension along a direction away from the display region, and an orthographic projection of the first shield layer on the plane of the display substrate is within the range of an orthographic projection of the second adhesive layer on the plane of the display substrate.

In an exemplary implementation mode, the bonding shield layer includes a second shield layer disposed in the first adhesive layer, the distance between an edge of a side of the second shield layer close to the display region and the boundary of the display region is less than or equal to 100 μm, and an orthographic projection of the second shield layer on the plane of the display substrate at least partially overlaps an orthographic projection of the cover plate shield layer on the plane of the display substrate.

In an exemplary implementation mode, the second shield layer is formed by blackening a portion of the first adhesive layer located in the bonding region, and the second shield layer extends from the lead region to the composite circuit region.

In an exemplary implementation mode, the bonding shield layer comprises a third shield layer and/or a fourth shield layer disposed on the polarizing layer, the distance between an edge of a side of the third shield layer or the fourth shield layer close to the display region and the boundary of the display region is less than or equal to 100 μm, and an orthographic projection of the third shield layer or the fourth shield layer on the plane of the display substrate at least partially overlaps an orthographic projection of the cover plate shield layer on the plane of the display substrate.

In an exemplary implementation mode, the first functional layer further includes a first stretch film disposed on a side of the polarizing layer close to the display substrate and a second stretch film disposed on a side of the first stretch film close to the display substrate, a stretch direction of the first stretch film intersects a stretch direction of the second stretch film, and an overlapped region of the first stretch film and the second stretch film forms an opaque third shield layer located in the bonding region.

In an exemplary implementation mode, the fourth shield layer is disposed on a side of the polarizing layer away from the display substrate, and is prepared and formed on the polarizing layer located in the bonding region by screen printing or inkjet printing.

In an exemplary implementation mode, a material of the fourth shield layer comprises a mixture of graphene and black graphite powder, or a mixture of graphene composite and black graphite powder, the fourth shield layer extends from the lead region to the composite circuit region, and an end of the fourth shield layer is connected to a ground pin in the composite circuit region.

In an exemplary implementation mode, the bonding region is further provided with an electrostatic lead configured to transmit static electricity on the cover plate layer to a ground pin in the composite circuit region.

In an exemplary implementation mode, the electrostatic lead includes a first electrostatic lead disposed in the display substrate, the first electrostatic lead extends from the lead region to the composite circuit region, and an end of the first electrostatic lead is connected to the ground pin in the composite circuit region; a connection groove is provided on the first adhesive layer and the polarizing layer, the second adhesive layer fills the connection groove and is connected with the first electrostatic lead, and the static electricity of the cover plate layer is transmitted to the ground pin through the cover plate shield layer, the second adhesive layer and the first electrostatic lead.

In an exemplary implementation mode, in a plane perpendicular to the display panel, the display substrate includes a drive circuit layer disposed on the base substrate, a light emitting structure layer disposed on a side of the drive circuit layer away from the base substrate, an encapsulation structure layer disposed on a side of the light emitting structure layer away from the base substrate, and a touch structure layer disposed on a side of the encapsulation structure layer away from the base substrate, the first electrostatic lead is disposed in the touch structure layer, the first electrostatic lead and a touch lead in the touch structure layer are disposed on the same layer.

In an exemplary implementation mode, the electrostatic lead include a second electrostatic lead disposed on a side of the polarizer away from the display substrate, the second electrostatic lead extends from the lead region to the composite circuit region, an end of the second electrostatic lead is connected to a ground pin in the composite circuit region, and the static electricity of the cover plate layer is transmitted to the ground pin through the cover plate shield layer, the second adhesive layer and the second electrostatic lead.

In an exemplary implementation mode, a material of the second electrostatic lead includes graphene or graphene composite, and is prepared and formed on the polarizing layer located in the bonding region by screen printing or inkjet printing.

In an exemplary implementation mode, the second functional layer includes at least a third adhesive layer disposed on a backlight side surface of the display substrate, a reinforcing layer disposed on a side of the third adhesive layer away from the display substrate, and a spacer disposed on a side of the reinforcing layer away from the display substrate, a material of the reinforcing layer comprises stainless steel, and a material of the third adhesive layer comprises pressure sensitive adhesive.

In an exemplary implementation mode, the third adhesive layer is disposed in the lead region, the bending region and the composite circuit region, the reinforcing layer is disposed in the lead region and the composite circuit region, or the reinforcing layer is disposed in the lead region, the bending region and the composite circuit region.

In an exemplary implementation mode, the reinforcing layers of the lead region and the composite circuit region are provided with a plurality of first reinforcing grooves, and groove depths of the plurality of first reinforcing grooves gradually increase in a direction close to the bending region.

In an exemplary implementation mode, the reinforcing layers of the lead region and the composite circuit region include at least an equal groove depth region and a variable groove depth region, the equal groove depth region is located on a side of the variable groove depth region close to the bending region, the groove depths of the plurality of first reinforcing grooves in the equal groove depth region are equal, and the groove depths of the plurality of first reinforcing grooves in the variable groove depth region gradually increase along a direction close to the bending region.

In an exemplary implementation mode, the width of the equal groove depth region is 80 to 120 μm, the width of the variable groove depth region is 180 to 250 μm, the width of the first reinforcing groove is 10 to 20 μm, and the spacing between adjacent first reinforcing grooves is 10 to 20 μm.

In an exemplary implementation mode, the groove depth of the first reinforcing groove in the equal groove depth region is 70% to 80% of the thickness of the reinforcing layer.

In an exemplary implementation mode, the reinforcing layer of the bending region is provided with a plurality of second reinforcing grooves, the groove depths of the plurality of second reinforcing grooves are equal to the thickness of the reinforcing layer.

In an exemplary implementation mode, the width of the second reinforcing groove is 10 to 20 μm and the spacing between adjacent second reinforcing grooves is 10 to 20 μm.

In an exemplary implementation mode, the second functional layer comprises at least a conductive paste layer disposed on a backlight side surface of the display substrate, a reinforcing layer disposed on a side of the conductive paste layer away from the display substrate, and a spacer disposed on a side of the reinforcing layer away from the display substrate, the material of the reinforcing layer comprises stainless steel, and the material of the conductive paste layer comprises graphene or a graphene composite.

In an exemplary implementation mode, the conductive paste layer is provided in the lead region, the bending region and the composite circuit region, an end of the conductive paste layer is connected to a ground pin in the composite circuit region, and the reinforcing layer is provided in the lead region and the composite circuit region.

In another aspect, an exemplary embodiment of the present disclosure also provides a display device including the above-described display panel.

In yet another aspect, an exemplary embodiment of the present disclosure provides a preparation method of a display panel, the display panel includes a display region and a bonding region located on a side of the display region, wherein the bonding region comprises a lead region, a bending region and a composite circuit region arranged sequentially in a direction away from the display region, the bending region is configured to flip the composite circuit region to a back of the display region by being bent; the preparation method comprising: forming a first functional layer and a second functional layer on a light exit side surface and a backlight side surface of a display substrate, respectively; the first functional layer of the bonding region at least comprises a first adhesive layer, a polarizing layer disposed on a side of the first adhesive layer away from the display substrate, a second adhesive layer disposed on a side of the polarizing layer away from the display substrate, and a cover plate layer disposed on a side of the second adhesive layer away from the display substrate; the first adhesive layer and the polarizing layer are disposed in the lead region, the bending region and the composite circuit region, a side of the cover plate layer close to the display substrate is provided with a cover plate shield layer, and at least one of the display substrate, the first adhesive layer and the polarizing layer is provided with a bonding shield layer, the distance between an edge of a side of the bonding shield layer close to the display region and the boundary of the display region is less than the distance between an edge of a side of the cover plate shield layer close to the display region and the boundary of the display region, and the boundary of the display region is an edge of a side of the display region close to the bonding region.

After the drawings and the detailed descriptions are read and understood, the other aspects may be comprehended.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display panel;

FIG. 2 is a schematic diagram of a structure of a display substrate;

FIG. 3 is a side view of the display substrate in FIG. 2;

FIG. 4 is a schematic diagram of a planar structure of a display region in a display substrate;

FIG. 5 is a schematic diagram of a sectional structure of a display region in a display substrate;

FIG. 6 is a schematic diagram of an equivalent circuit of a pixel drive circuit;

FIG. 7 is a schematic diagram of a cross-sectional structure of a display panel;

FIG. 8 is a schematic diagram of a cross-sectional structure of a display panel according to an exemplary embodiment of the present disclosure;

FIG. 9 is a schematic diagram of a cross-sectional structure of another display panel according to an exemplary embodiment of the present disclosure;

FIG. 10 is a schematic diagram of a cross-sectional structure of yet another display panel according to an exemplary embodiment of the present disclosure;

FIG. 11 is a schematic diagram of a shield film according to an exemplary embodiment of the present disclosure;

FIG. 12 is a schematic diagram of a cross-sectional structure of yet another display panel according to an exemplary embodiment of the present disclosure;

FIG. 13 is a schematic diagram of a cross-sectional structure of yet another display panel according to an exemplary embodiment of the present disclosure;

FIG. 14 is a schematic diagram of a planar structure of a first electrostatic lead according to an exemplary embodiment of the present disclosure;

FIG. 15 is a schematic diagram of a cross-sectional structure of yet another display panel according to an exemplary embodiment of the present disclosure;

FIG. 16 is a schematic diagram of a planar structure of a second electrostatic lead according to an exemplary embodiment of the present disclosure;

FIG. 17 is a schematic diagram of a cross-sectional structure of a second electrostatic lead according to an exemplary embodiment of the present disclosure;

FIG. 18 is a schematic diagram of a cross-sectional structure of yet another display panel according to an exemplary embodiment of the present disclosure;

FIG. 19 is a schematic structural diagram of a reinforcing layer according to an exemplary embodiment of the present disclosure;

FIG. 20 is a schematic diagram of a cross-sectional structure of yet another display panel according to an exemplary embodiment of the present disclosure;

FIG. 21 is a schematic diagram of a cross-sectional structure of yet another display panel according to an exemplary embodiment of the present disclosure;

FIG. 22 is a schematic diagram of a cross-sectional structure of yet another display panel according to an exemplary embodiment of the present disclosure.

Reference signs are described as follows.

| | | |
|---|---|---|
| 10—display substrate; | 11—first electrostatic lead; | 12—second electrostatic lead; |
| 20—first adhesive layer; | 30—polarizing layer; | 31—first stretch film; |
| 32—second stretch film; | 33—connection groove; | 40—second adhesive layer; |
| 50—cover plate layer; | 51—cover plate shield layer; | 61—back film layer; |
| 62—first heat dissipation layer; | 63—second heat dissipation layer; | 64—protection layer; |
| 70—spacer; | 80—third adhesive layer; | 90—reinforcing layer; |
| 91—first reinforcing groove; | 92—second reinforcing groove; | 100—display region; |
| 101—first shield layer; | 102—second shield layer; | 103—third shield layer; |
| 104—fourth shield layer; | 110—conductive paste layer; | 200—bonding region; |
| 210—lead region; | 220—bending region; | 230—composite circuit region; |
| 240—integrated circuit; | 250—flexible printed board; | 300— bezel region; |
| 301—base substrate; | 302—drive structure layer; | 303—light emitting structure layer; |
| 304—encapsulation structure layer; | 305—touch structure layer. | |

### DETAILED DESCRIPTION

To make the objectives, technical solutions, and advantages of the present disclosure clearer, the embodiments of the present disclosure will be described in detail below in combination with the accompany drawings. It is to be noted that the implementations may be implemented in various forms. Those of ordinary skill in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other in case of no conflicts.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display panel and a quantity of sub-pixels in each pixel are not limited to numbers shown in the drawings. The drawings described in the present disclosure are structural schematic diagrams only, and one mode of the present disclosure is not limited to shapes, numerical values, or the like shown in the drawings.

Ordinal numerals “first”, “second”, “third”, etc., in the specification are set not to form limits in number but only to avoid the confusion of composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limits to the present disclosure. The positional relationships between the composition elements may be changed as appropriate according to the direction where each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, the term may be fixed connection, or detachable connection, or integral connection. The term may be mechanical connection or electric connection. The term may be direct connection, or indirect connection through an intermediate, or communication inside two elements. Those of ordinary skill in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. It is to be noted that in the specification, the channel region refers to a main region that a current flows through.

In the specification, a first electrode may be the drain electrode, and a second electrode may be the source electrode. Alternatively, the first electrode may be a source electrode, and the second electrode may be a drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode” may be exchanged in the specification.

In the specification, “electric connection” includes connection of the composition elements through an element with a certain electric action. “An element with a certain electric action” is not particularly limited as long as electric signals between the connected composition elements may be sent and received. Examples of “an element with a certain electric action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 1000 or less, and thus also includes a state in which the angle is 850 or more and 950 or less.

In the specification, a “film” and a “layer” are interchangeable. For example, a “conductive layer” may be replaced with a “conductive film” sometimes. Similarly, an “insulating film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc.

There may be some small deformations caused by tolerance, and there may be chamfer, arc edge, deformation, etc. In the present disclosure, “about” refers to that a boundary is not defined so strictly and numerical values within process and measurement error ranges are allowed.

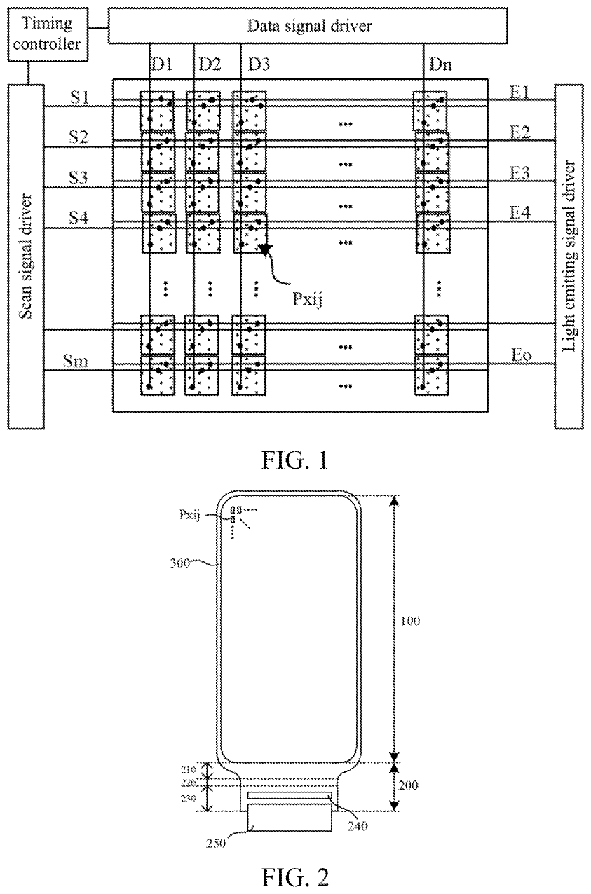

FIG. 1 is a schematic structural diagram of a display panel. As shown in FIG. 1, the display panel may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, wherein both of i and j may be natural numbers. At least one of the sub-pixels Pxij may include a circuit unit and a light emitting unit connected to the circuit unit, wherein the circuit unit may include, at least, a pixel drive circuit that is connected to a scan signal line, a data signal line and a pixel drive circuit, respectively. In an exemplary implementation, the timing controller may provide a grayscale value and a control signal suitable for the specification of the data signal driver to the data signal driver, may provide a clock signal, a scan start signal, etc. suitable for the specification of the scan driver to the scan driver, and may provide a clock signal, an emission stop signal, etc. suitable for the specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a row of pixels as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

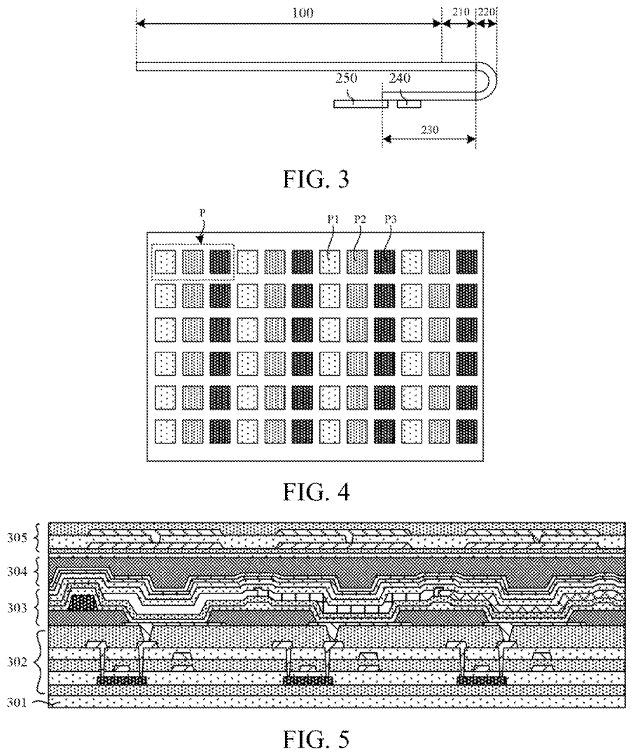

In an exemplary implementation mode, on a plane perpendicular to the display panel, the display panel may include a display substrate, a first functional layer disposed on a light exit surface of the display substrate, and a second functional layer disposed on a backlight surface of the display substrate. FIG. 2 is a schematic diagram of a structure of a display substrate, illustrating the state of the bonding region before being bent, and FIG. 3 is a side view of the display substrate in FIG. 2, illustrating the bent state of the bonding region after being bent. As shown in FIGS. 2 and 3, on a plane parallel to the display panel, the display substrate may include at least a display region 100, a bonding region 200 located on a side of the display region 100, and a bezel region 300 located on other sides of the display region 100. In an exemplary implementation mode, the display region 100 may be a planar region including a plurality of sub-pixels Pxij that form a pixel array, the plurality of sub-pixels Pxij are configured to display a dynamic picture or a static image, and the display region 100 may be referred to as an Active Area (AA). In an exemplary implementation, the display substrate may be deformable, e.g., may be crimped, bent, folded, or curled.

In an exemplary implementation mode, the bonding region 200 may include a lead region 210, a bending region 220 and a composite circuit region 230 arranged sequentially in a direction away from the display region 100. The lead region 210 may be connected to the display region 100 and may include at least a plurality of data transmission lines configured to connect data signal lines of the display region. The bending region 220 may be connected to the lead region 210, may include a composite insulating layer provided with a groove, and is configured to bend and attach the bonding region to a back of the display region 100 in a bending manner, so that the bonding region 200 may overlap the display region 100 in a direction perpendicular to a plane of the display region. The composite circuit region 230 may include at least a drive chip region and a bonding pin region, an integrated circuit (IC) 240 may be bound and connected to the drive chip region, and a Flexible Printed Circuit (FPC) 250 may be bound and connected to the bonding pin region.

In an exemplary implementation mode, the integrated circuit 240 may be bound and connected to the drive chip region by an anisotropic conductive film or other ways, the integrated circuit 240 may generate a drive signal required for driving sub-pixels, and may provide the drive signal to the sub-pixels in the display region 100. For example, the drive signal may be a data signal that drives luminance of the sub-pixel. In an exemplary implementation, the bonding pin region may include a plurality of pins (PIN) to which the flexible printed board 250 may be bonded and connected.

In an exemplary implementation mode, the bezel region 300 may include a circuit region, a power supply line region, and a crack dam region and a cutting region which are sequentially disposed along the direction away from the display region 100. The circuit region is connected with the display region 100 and may at least include a gate drive circuit which is connected with a scan signal line and a light emitting control line of a pixel drive circuit in the display region 100. The power supply line region is connected to the circuit region and may at least include a bezel power supply trace that extends along a direction parallel to a boundary of the display region and is connected with a cathode in the display region 100. The crack dam region is connected to the power supply line region and may at least include a plurality of cracks arranged on the composite insulation layer. The cutting region is connected to the crack dam region and may at least include a cutting groove arranged on the composite insulation layer, and the cutting groove is configured that a cutting device cuts along the cutting groove respectively after preparation of all film layers of the display substrate are completed.

In an exemplary implementation, the fan-out region in the bonding region 200 and the power supply line region in the bezel region 300 may be provided with a first isolation dam and a second isolation dam, the first isolation dam and the second isolation dam may extend in a direction parallel to the boundary of the display region 100, forming an annular structure surrounding the display region 100, wherein the boundary of the display region is an edge on a side of the display region close to the bonding region or close to the bezel region.

FIG. 4 is a schematic diagram of a planar structure of a display region in a display substrate. As shown in FIG. 4, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light-emitting unit, wherein the circuit unit may at least include a pixel drive circuit connected with a scan signal line, a data signal line, and a light-emitting signal line, respectively, and configured to receive a data voltage transmitted by the data signal line and output a corresponding current to the light-emitting unit under control of the scan signal line and the light-emitting signal line. The light-emitting unit in each sub-pixel is connected with a pixel drive circuit of a sub-pixel where the light-emitting unit is located, and is configured to emit light with corresponding brightness in response to a current output by the pixel drive circuit connected with the light-emitting unit.

In an exemplary implementation mode, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged side by side horizontally, side by side vertically, or in a manner like a Chinese character “ [symbol] ”, etc., which is not limited here in the present disclosure.

In an exemplary implementation mode, the pixel unit may include four sub-pixels. For example, the four sub-pixels may include a red sub-pixel, a green sub-pixel, a blue sub-pixel, and a white sub-pixel that emits white (W) light. As another example, the four sub-pixels may include a red sub-pixel, a blue sub-pixel, and two green sub-pixels. In exemplary implementations, the four sub-pixels may be arranged side by side horizontally, side by side vertically, or in a square or a diamond, which is not limited in the present disclosure.

FIG. 5 is a schematic diagram of a sectional structure of a display region in a display substrate, illustrating a structure of three sub-pixels in the display region. As shown in FIG. 5, on a plane perpendicular to the display substrate, the display substrate may include a base substrate 101, a drive circuit layer 102 disposed on the base substrate 101, a light emitting structure layer 103 disposed on a side of the drive circuit layer 102 away from the base substrate, an encapsulation structure layer 104 disposed on a side of the light emitting structure layer 103 away from the base substrate, and a touch structure layer 105 disposed on a side of the encapsulation structure layer 104 away from the base substrate. In some possible implementations, the display substrate may include other film layers, and the present disclosure is not limited thereto.

In an exemplary implementation mode, the base substrate 101 may be a flexible base substrate. The flexible base substrate may include a first flexible material layer, a first inorganic material layer, a semiconductor layer, a second flexible material layer and a second inorganic material layer which are stacked. Materials of the first flexible material layer and the second flexible material layer may be polyimide (PI), polyethylene terephthalate (PET) or a polymer soft film with surface treatment. Materials of the first inorganic material layer and the second inorganic material layer may be silicon nitride (SiNx) or silicon oxide (SiOx), for improving water and oxygen resistance of the base substrate, and a material of the semiconductor layer may be amorphous silicon (a-si).

In an exemplary implementation mode, the drive circuit layer 102 may include a plurality of circuit units which may include at least a pixel drive circuit which may include at least a plurality of transistors and storage capacitors. In an exemplary implementation mode, the drive structure layer 102 of each circuit unit may include a first insulating layer arranged on the base substrate; an active layer arranged on the first insulating layer; a second insulating layer overlying the active layer; a gate electrode and a first polar plate arranged on the second insulating layer; a third insulating layer overlying the gate electrode and the first polar plate; a second polar plate arranged on the third insulating layer; a fourth insulating layer overlying the second polar plate, the second insulating layer, the third insulating layer and the fourth insulating layer are provided with active vias, and the active vias expose the active layer; a source electrode and a drain electrode provided on the fourth insulating layer, wherein the source electrode and the drain electrode are respectively connected with the active layer through the active vias; a planarization layer covering the above-mentioned structures, wherein a connection via is provided on the planarization layer, and the connection via exposes the drain electrode. The active layer, the gate electrode, the source electrode and the drain electrode form a transistor, and the first electrode plate and the second electrode plate form a storage capacitor.

In an exemplary implementation mode, the light emitting structure layer 103 may include at least a plurality of light emitting units, the light emitting unit may include at least an anode, a pixel definition layer, an organic light emitting layer, and a cathode, and the anode may be disposed on the planarization layer and connected to a drain electrode of the transistor through a connection via opened on the planarization layer; the pixel definition layer is arranged on the anode, and a pixel opening is provided on the pixel definition layer, and the pixel opening exposes the anode; the organic light emitting layer is connected with the anode through the pixel opening, the cathode is arranged on the organic light emitting layer, and the cathode is connected with the organic light emitting layer; the organic light emitting layer emits light of a corresponding color under driving of the anode and the cathode.

In an exemplary implementation, the encapsulation layer 104 may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is disposed between the first encapsulation layer and the third encapsulation layer to form an inorganic material/organic material/inorganic material laminated structure and ensure that external water and oxygen cannot enter the light emitting structure layer 103.

In an exemplary implementation mode, the touch structure layer 105 may include at least a first touch insulating layer, a first touch metal layer disposed on the first touch insulating layer, a second touch insulating layer covering the first touch metal layer, a second touch metal layer disposed on the second touch insulating layer, and a touch protective layer covering the second touch metal layer, the first touch metal layer may include a plurality of bridge electrodes, the second touch metal layer may include a plurality of first touch electrodes and second touch electrodes, and the first touch electrodes or second touch electrodes may be connected to the bridge electrodes through vias.

FIG. 6 is a schematic diagram of an equivalent circuit of a pixel drive circuit. In an exemplary implementation mode, the pixel drive circuit may have a structure of 3T1C, 4T1C, 5T1C, 5T2C, 6T1C, 7T1C, or 8T1C. As shown in FIG. 6, the pixel drive circuit may include seven transistors (a first transistor T1 to a seventh transistor T7), and one storage capacitor C. The pixel drive circuit is connected with six signal lines (a data signal line D, a first scan signal line S1, a second scan signal line S2, a light-emitting signal line E, an initial signal line INIT, and a first power supply line VDD) respectively.

In an exemplary implementation, the pixel drive circuit may include a first node N1, a second node N2, and a third node N3. Herein, the first node N1 is respectively connected with a first electrode of the third transistor T3, a second electrode of the fourth transistor T4, and a second electrode of the fifth transistor T5, the second node N2 is respectively connected with a second electrode of the first transistor, a first electrode of the second transistor T2, a gate electrode of the third transistor T3, and a second end of the storage capacitor C, and the third node N3 is respectively connected with a second electrode of the second transistor T2, a second electrode of the third transistor T3, and a first electrode of the sixth transistor T6.

In an exemplary implementation mode, a first end of the storage capacitor C is connected with the first power supply line VDD, and a second end of the storage capacitor C is connected with a second node N2, namely the second end of the storage capacitor C is connected with a gate electrode of the third transistor T3.

A gate electrode of the first transistor T1 is connected with the second scan signal line S2, a first electrode of the first transistor T1 is connected with the initial signal line INIT, and a second electrode of the first transistor is connected with the second node N2. When a scan signal with an on-level is applied to the second scan signal line S2, the first transistor T1 transmits an initialization voltage to the gate electrode of the third transistor T3 so as to initialize a charge amount of the gate electrode of the third transistor T3.

A gate electrode of the second transistor T2 is connected to the first scan signal line S1, a first electrode of the second transistor T2 is connected to the second node N2, and a second electrode of the second transistor T2 is connected to a third node N3. When a scan signal with an on-level is applied to the first scan signal line S1, the second transistor T2 enables the gate electrode of the third transistor T3 to be connected with a second electrode of the third transistor T3.

The gate electrode of the third transistor T3 is connected with the second node N2, namely the gate electrode of the third transistor T3 is connected with the second end of the storage capacitor C, a first electrode of the third transistor T3 is connected with a first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the gate electrode and the first electrode of the third transistor T3.

A gate electrode of the fourth transistor T4 is connected to the first scan signal line S1, a first electrode of the fourth transistor T4 is connected to the data signal line D, and a second electrode of the fourth transistor T4 is connected to the first node N1. The fourth transistor T4, may be referred to as a switching transistor, a scanning transistor, etc., and the fourth transistor T4 enables a data voltage of the data signal line D to be input into the pixel drive circuit when a scan signal with an on-level is applied to the first scan signal line S1.

A gate electrode of the fifth transistor T5 is connected with the light-emitting signal line E, a first electrode of the fifth transistor T5 is connected with the first power supply line VDD, and a second electrode of the fifth transistor T5 is connected with the first node N1. A gate electrode of the sixth transistor T6 is connected with the light-emitting signal line E, a first electrode of the sixth transistor T6 is connected with the third node N3, and a second electrode of the sixth transistor T6 is connected with a first electrode of the light-emitting unit EL. The fifth transistor T5 and the sixth transistor T6 may be referred to as light emitting transistors. When a light-emitting signal with an on-level is applied to the light-emitting signal line E, the fifth transistor T5 and the sixth transistor T6 enable the light emitting unit EL to emit light by forming a drive current path between the first power supply line VDD and the second power supply line VSS.

A gate electrode of the seventh transistor T7 is connected with the second scan signal line S2, a first electrode of the seventh transistor T7 is connected with the initial signal line INIT, and a second electrode of the seventh transistor T7 is connected with the first electrode of the light-emitting unit EL. When a scan signal with an on-level is applied to the second scan signal line S2, the seventh transistor T7 transmits an initialization voltage to the first electrode of the light-emitting unit EL so as to initialize a charge amount accumulated in the first electrode of the light-emitting unit EL or release a charge amount accumulated in the first electrode of the light-emitting unit EL.

In an exemplary implementation mode, the light-emitting unit EL may be an OLED including a first electrode (anode), an organic light emitting layer, and a second electrode (cathode) which are stacked, or may be a QLED including a first electrode (anode), a quantum-dot light emitting layer, and a second electrode (cathode) which are stacked.

In an exemplary implementation mode, a second electrode of the light-emitting unit EL is connected with the second power supply line VSS, a signal of the second power supply line VSS is a low-level signal continuously provided, and a signal of the first power supply line VDD is a high-level signal continuously provided.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation mode, for the first transistor T1 to the seventh transistor T7, low temperature poly silicon thin film transistors may be adopted, or oxide thin film transistors may be adopted, or both a low temperature poly silicon thin film transistor and an oxide thin film transistor may be adopted. An active layer of a low temperature poly silicon thin film transistor may be made of Low Temperature Poly Silicon (LTPS for short), and an active layer of an oxide thin film transistor may be made of an oxide semiconductor (Oxide). The low temperature poly-silicon thin film transistors have advantages such as high migration rate and fast charging, and the oxide thin film transistors have advantages such as low leakage current. The low temperature poly-silicon thin film transistors and the oxide thin film transistors are integrated on one display substrate to form a low temperature polycrystalline oxide (LTPO) display substrate, so that the advantages of both the low temperature poly-silicon thin film transistors and the oxide thin film transistors can be utilized, low-frequency driving can be realized, power consumption can be decreased, and display quality can be improved.

Taking all of the seven transistors being P-type transistors as an example, the operation process of the pixel drive circuit may include the following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is a low-level signals, which causes the first transistor T1 and the seventh transistor T7 to be turned on. The first transistor T1 is turned on such that the initial voltage of the initial signal line INIT is provided to a second node N2 to initialize the storage capacitor C to clear an original data voltage in the storage capacitor. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization. The signals of the first scan signal line S1 and the light emitting signal line E are high-level signals, so that the second transistor T2, the fourth transistor T4, the fifth transistor T5 and the sixth transistor T6 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2 and the fourth transistor T4 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The signal of the second scan signal line S2 is the high-level signal, so that the first transistor T1 and the seventh transistor T7 are turned off. The signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is a low-level signal, so that the fifth transistor T5 and the sixth transistor T6 are turned on, and a power voltage output by the first power supply line VDD provides a drive voltage to the first electrode of the OLED through the turned-on fifth transistor T5, third transistor T3, and sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata−|Vth|, so the drive current of the third transistor T3 is as follows.

I=K*(Vgs−Vth)²=K*[(Vdd−Vd+|Vth|)−Vth]²=K*[(Vdd−Vd]²

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

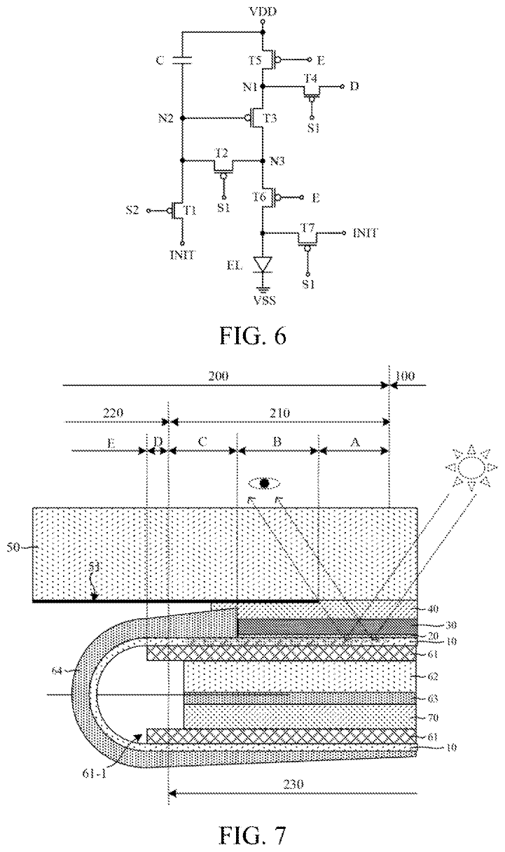

FIG. 7 is a schematic diagram of a cross-sectional structure of a display panel, illustrating the state of the bonding region after being bent. As shown in FIG. 7, on a plane parallel to the display region, the display panel may include at least a display region 100 and a bonding region 200 located on a side of the display region 100. The bonding region 200 may at least include a lead region 210, a bending region 220, and a composite circuit region 230 sequentially arranged along a direction away from the display region 100, the lead region 210 may be connected to the display region 100, the bending region 220 may be connected to the lead region 210, the composite circuit region 230 may be connected to the bending region 220, the bending region 220 is provided with a bending groove, the bending region 220 can attach the composite circuit region 230 to the back of the display region 100 in a bending manner, the composite circuit region 230 may overlap the display region 100 in a direction perpendicular to the plane of the display region.

In an exemplary implementation mode, on a plane perpendicular to the display panel, the display panel may include a display substrate 10, a first functional layer disposed on a surface (a light exit surface) of a first side of the display substrate 10, and a second functional layer disposed on a surface (a backlight surface) of a second side of the display substrate 10. The first functional layer may include at least a first adhesive layer 20 disposed on a surface of a first side of the display substrate 10, a polarizing layer 30 disposed on a side of the first adhesive layer 20 away from the display substrate 10, a second adhesive layer 40 disposed on a side of the polarizing layer 30 away from the display substrate 10, and a cover plate layer 50 disposed on a side of the second adhesive layer 40 away from the display substrate 10. The second functional layer may include at least a back film layer 61 disposed on a surface of a second side of the display substrate 10, a first heat dissipation layer 62 disposed on a side of the back film layer 61 away from the display substrate 10, a second heat dissipation layer 63 disposed on a side of the first heat dissipation layer 62 away from the display substrate 10, and a spacer 70 disposed on a side of the second heat dissipation layer 63 away from the display substrate 10.

In an exemplary implementation mode, the first adhesive layer 20 is configured to adhere the polarizing layer 30 on the surface of the first side of the display substrate 10 and the first adhesive layer 20 and the polarizing layer 30 may be located only in the display region 100 and the lead region 210. In an exemplary implementation mode, the first adhesive layer 20 may be a Pressure Sensitive Adhesive (PSA).

In an exemplary implementation mode, the second adhesive layer 40 is configured to adhere the cover plate layer 50 on the polarizing layer 30, the second adhesive layer 40 may be located only in the display region 100 and the lead region 210, and the cover plate layer 50 may extend from the display region 100 to the bending region 220. In an exemplary implementation mode, the second adhesive layer 40 may be Optically Clear Adhesive (OCA), and the cover plate layer 50 may be Cover Glass (CG) or plastic Colorless Polyimide (CPI) having flexible characteristics.

In an exemplary implementation mode, the back film layer 61 is configured to support the display substrate 10, and may be provided in the display region 100 and the bonding region 200, the back film layer 61 of the bonding region 200 is provided with a back film opening 61-1, the position of the back film opening 61-1 may correspond to the bending region 220, and the back film layer 61 in the back film opening 61-1 is removed, i.e., the back film layer 61 of the bonding region 200 is provided in the lead region 210 and the composite circuit region 230, respectively. In an exemplary implementation mode, the back film layer 61 may be made of a low modulus film material of a polymer, such as a flexible film material such as polyolefin and polyurethane.

In an exemplary implementation mode, the first heat dissipation layer 62 and the second heat dissipation layer 63 are configured to dissipate heat during operation of the display substrate and may be located only in the display region 100 and the lead region 210. In an exemplary implementation mode, the first heat dissipation layer 62 may include a mesh paste layer and a buffer layer which may be made of foam material, for example, and the second heat dissipation layer 63 may include a copper foil layer.

In an exemplary implementation mode, the spacer 70 is configured to be attached to the second heat dissipation layer 63 of the lead region 210 and the back film layer 61 of the composite circuit region 230 respectively and may be located only in the display region 100 and the lead region 210.

In an exemplary implementation mode, the bending region 220 of the display panel includes a protective paste layer 64 disposed on a surface of a first side of the display substrate 10, the protective paste layer 64 may extend from the lead region 210 to the composite circuit region 230 to include the display substrate of the bending region 220, the protective paste layer 64 of the lead region 210 may be located on a side of the polarizing layer 30 away from the display region, and the protective paste layer 64 of the composite circuit region 230 may cover all of the composite circuit region 230.

In an exemplary implementation mode, a side of the cover plate layer (CG) 50 facing the display substrate 10 is provided with a cover plate shield layer 51 configured to shield the bonding region. In an exemplary implementation mode, the cover plate shield layer 51 may be made of black ink and may be prepared on the cover plate layer 50 in a coating manner.

In an exemplary implementation mode, the lead region 210 of the bonding region 200 may be divided into a first sub-region A, a second sub-region B, and a third sub-region C, and the first sub-region A, the second sub-region B, and the third sub-region C may be sequentially disposed in a direction away from the display region. The first sub-region A may be a region between the boundary of the display region and an edge of a side of the cover plate shield layer 51 close to the display region, the second sub-region B may be a region between an edge of a side of the cover plate shield layer 51 close to the display region and an edge of a side of the polarizing layer 30 away from the display region, and the third sub-region C may be a region between an edge of a side of the polarizing layer 30 away from the display region and a boundary of the lead region 210 (a boundary of a side of the lead region 210 away from the display region), the boundary of the display region is an edge of a side of the display region 100 close to the bonding region 200, the boundary of the lead region 210 is also an edge of a side of the bending region 220 close to the display region, and an edge of a side of the polarizing layer 30 away from the display region is also an edge of a side of the protective layer 64 close to the display region.

In an exemplary implementation mode, the bending region 220 may be divided into at least a fourth region D and a fifth region E which may be sequentially disposed in a direction away from the display region. The fourth region D may be a region between a boundary of a side of the bending region 220 close to the display region and a side wall on a side of the back film opening 61-1 on the back film layer 61 close to the display region, and the fifth region E may be a region other than a side wall on a side of the back film opening 61-1 close to the display region, the position of the side wall of the back film opening 61-1 on the back film layer 61 also is the position of the side wall of the bending groove in the bonding region.

With development of OLED display technologies, consumers have higher requirements for a display effect of a display product. An extremely narrow bezel has become a new trend in development of display products. Therefore, bezel narrowing or even a bezelless design has attracted more and more attention in a design of an OLED display product. In the display substrate with the structural form shown in FIG. 7, the first sub-region A, the second sub-region B, the third sub-region C, and the fourth region D together determine the width of the bonding region (referred to as the lower bezel width) of the display substrate, and the display substrate with the structural form has a problem that the width of the bonding region is large. Research shows that, the width of the first sub-region A is generally set to 200 μm to 300 μm since the process tolerance for preparing the cover plate shield layer 51 on the cover plate layer 50 is large, and if the width of the first sub-region A is forcibly reduced, there is a risk that the cover plate shield layer 51 shields the display region. Since the second sub-region B is a planarization region formed by the second adhesive layer 40, the width of the second sub-region B is generally set to 300 μm to 400 μm. If the width of the second sub-region B is forcibly reduced, the planarization region formed by the second adhesive layer 40 will be reduced, and the lap region between the polarizing layer 30 and the cover plate shield layer 51 will be reduced, there is a risk of attachment bubbles, resulting in attachment bubbles at a junction of the polarizing layer 30 and the protective layer 64. Since the third sub-region C is an extended region of the protective layer 64, the width of the third sub-region C is generally set to 300 to 400 μm. If the width of the third sub-region C is forcibly reduced, the positions of a boundary of a side of the protective layer 64 close to the display region (i.e., a boundary of a side of the polarizing layer 30 away from the display region) and a boundary of a side of the second adhesive layer 40 away from the display region side are concentrated, and there is a risk that the protective layer will crack. Since the boundary of the fourth region D is at a position of the side wall on the back film opening 61-1, the width of the fourth region D is usually set to be 100 μm to 150 μm. If the width of the fourth region D is forcibly reduced, the reserved cutting tolerance and attachment tolerance of the back film layer cannot be guaranteed, and the shape of the bending arc in the bending region is affected, there is a risk that the display substrate will crack.

In an exemplary implementation mode, the display substrate with the structural form shown in FIG. 7 also has poor reflection silver edges and poor light leakage at the boundary of the display region. Research shows that, the display substrate has a first sub-region A due to the process tolerance of the cover plate shield layer 51. When external light passes through the cover plate layer 50 and is incident on the boundary region of the display substrate, because some regions of the bonding region are provided with touch leads and some regions are not provided with touch leads, the reflected light in the region where the touch leads are provided is weak (the touch leads in the display substrate reflect light), and the reflected light in the region where the touch leads are not provided is strong (power supply lines in the display substrate reflect light), thus resulting in poor reflection silver edges at the boundary of the display region. In addition, since there is a void between the cover plate shield layer 51 and the boundary of the display region (i.e., the first sub-region A is not provided with a shield layer), poor light leakage or poor imaginary edges occur at the boundary of the display region.

In an exemplary implementation mode, the display substrate with the structural form shown in FIG. 7 also has poor greening at the boundary of the display region. Research shows that, when the surface of the cover plate layer 50 is rubbed to generate static electricity, induced charges appear the internal polarization of the back film layer. Because the display substrate lacks static electricity dissipation path, there is no static electricity release path, and static electricity accumulation affects characteristics of transistors in the pixel drive circuit, resulting in transistor characteristics drift and poor greening at a lower edge at a low grayscale. At present, the solutions in the industry can only reduce the greening dissipation time to a certain extent, but cannot eliminate the poor greening under high electrostatic voltage.

In an exemplary implementation mode, the display substrate with the structural form shown in FIG. 7 also has a problem of large thickness. The research shows that, in the display substrate, the thickness of the back film layer 61 is about 50 μm to 80 μm, and the thickness of the first heat dissipation layer 62 and the second heat dissipation layer 63 is about 180 μm to 250 μm, so that the total thickness of the back film and the heat dissipation film is about 230 μm to 330 μm, which makes the overall thickness of the display panel thicker. If a thinning scheme of reducing the thickness of the back film layer and heat dissipation layer is directly adopted, cracks will appear at an edge of the bending region, and there is a risk of bright lines. In addition, in order to effectively protect the bending arc region, the protective layer 64 in the display substrate is thicker, and the thickness of the protective layer 64 is about 70 μm to 100 μm.

If the thinning scheme of reducing the thickness of the polarizing layer 30 and the second adhesive layer 40 is directly adopted, the protective layer 64 will be thinned accordingly, and the protective layer 64 will have a problem of uneven coating, and the protective effect of the protective layer 64 on the bending arc becomes worse, cracks are easy to appear in the bending region, and even poor glue breakage occurs.

In an exemplary implementation mode, the display substrate with the structural form shown in FIG. 7 also has a problem of insufficient support for the back film layer. Research shows that, when the display substrate is applied to an Under Display Camera (UDC), in order to improve the light transmittance of a camera hole (Hole), the back film layer is made of an optical back film material, which not only has the problem of insufficient support of the back film layer, but also has the problem of cracks on an edge of the bending region, and there is a risk of bright lines. Although the first heat dissipation layer and the second heat dissipation layer can be extended to the bending region to improve the support, the outward expansion of the heat dissipation layer will not only increase the radius of the bending arc and the width of the bonding region, but also increase the difficulty of the attachment process of the heat dissipation layer and reduce the production efficiency. If the attachment pressure of the heat dissipation layer is small, the edge of the heat dissipation layer will be warped after being attached. If the attachment pressure of the heat dissipation layer is increased, there is a risk of cracks at the edge of the bending region.

Exemplary embodiments of the present disclosure provide a display panel including a display region and a bonding region located on a side of the display region, the bonding region includes a lead region, a bending region and a composite circuit region arranged sequentially in a direction away from the display region, the bending region is configured to flip the composite circuit region to a back of the display region by being bent; in a plane perpendicular to the display panel, the bonding region includes a display substrate, a first functional layer on a light exit side surface of the display substrate, and a second functional layer on a backlight side surface of the display substrate, the first functional layer at least includes a first adhesive layer, a polarizing layer disposed on a side of the first adhesive layer away from the display substrate, a second adhesive layer disposed on a side of the polarizing layer away from the display substrate, and a cover plate layer disposed on a side of the second adhesive layer away from the display substrate; the first adhesive layer and the polarizing layer are arranged in the lead region, the bending region and the composite circuit region, a side of the cover plate layer close to the display substrate is provided with a cover plate shield layer, and at least one of the display substrate, the first adhesive layer and the polarizing layer is provided with a bonding shield layer, the distance between an edge of a side of the bonding shield layer close to the display region and the boundary of the display region is less than the distance between an edge of a side of the cover plate shield layer close to the display region and the boundary of the display region, and the boundary of the display region is an edge of a side of the display region close to the bonding region.

In an exemplary implementation mode, the bonding shield layer includes a first shield layer disposed in the display substrate, the distance between an edge of a side of the first shield layer close to the display region and the boundary of the display region is less than or equal to 10 μm, and an orthographic projection of the first shield layer on a plane of the display substrate at least partially overlaps an orthographic projection of the cover plate shield layer on the plane of the display substrate.

In another exemplary implementation mode, the bonding shield layer includes a second shield layer disposed in the first adhesive layer, the distance between an edge of a side of the second shield layer close to the display region and the boundary of the display region is less than or equal to 100 μm, and an orthographic projection of the second shield layer on the plane of the display substrate at least partially overlaps an orthographic projection of the cover plate shield layer on the plane of the display substrate.

In yet another exemplary implementation mode, the bonding shield layer comprises a third shield layer and/or a fourth shield layer disposed on the polarizing layer, the distance between an edge of a side of the third shield layer or the fourth shield layer close to the display region and the boundary of the display region is less than or equal to 100 μm, and an orthographic projection of the third shield layer or the fourth shield layer on the plane of the display substrate at least partially overlaps an orthographic projection of the cover plate shield layer on the plane of the display substrate.

In an exemplary implementation mode, the bonding region is further provided with an electrostatic lead configured to transmit static electricity on the cover plate layer to a ground pin in the composite circuit region.

In an exemplary implementation mode, the electrostatic lead includes a first electrostatic lead disposed in the display substrate, the first electrostatic lead extends from the lead region to the composite circuit region, and an end of the first electrostatic lead is connected to the ground pin in the composite circuit region; a connection groove is provided on the first adhesive layer and the polarizing layer, the second adhesive layer fills the connection groove and is connected with the first electrostatic lead, and the static electricity of the cover plate layer is transmitted to the ground pin through the cover plate shield layer, the second adhesive layer and the first electrostatic lead.

In another exemplary implementation mode, the electrostatic lead include a second electrostatic lead disposed on a side of the polarizer away from the display substrate, the second electrostatic lead extends from the lead region to the composite circuit region, an end of the second electrostatic lead is connected to a ground pin in the composite circuit region, and the static electricity of the cover plate layer is transmitted to the ground pin through the cover plate shield layer, the second adhesive layer and the second electrostatic lead.

In an exemplary implementation mode, the second functional layer includes at least a third adhesive layer disposed on a backlight side surface of the display substrate, a reinforcing layer disposed on a side of the third adhesive layer away from the display substrate, and a spacer disposed on a side of the reinforcing layer away from the display substrate, a material of the reinforcing layer comprises stainless steel, and a material of the third adhesive layer comprises pressure sensitive adhesive.

In an exemplary implementation mode, the second functional layer comprises at least a conductive paste layer disposed on a backlight side surface of the display substrate, a reinforcing layer disposed on a side of the conductive paste layer away from the display substrate, and a spacer disposed on a side of the reinforcing layer away from the display substrate, the material of the reinforcing layer comprises stainless steel, and the material of the conductive paste layer comprises graphene or a graphene composite.

The technical solution of the present disclosure is described in detail below by means of specific embodiments.

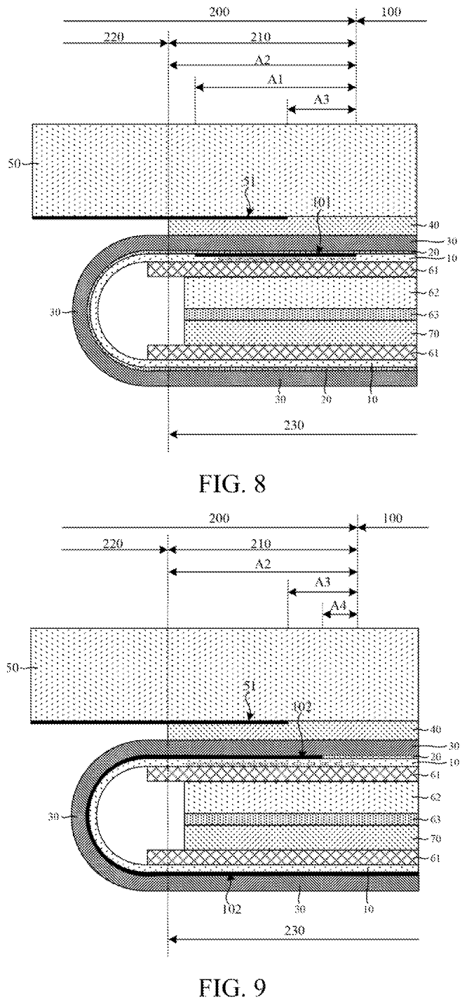

FIG. 8 is a schematic diagram of a cross-sectional structure of a display panel according to an exemplary embodiment of the present disclosure, illustrating the state of the bonding region after being bent. As shown in FIG. 8, on a plane parallel to the display region, the display panel according to an exemplary embodiment of the present disclosure may include at least a display region 100 and a bonding region 200 located on a side of the display region 100, and the bonding region 200 may include at least a lead region 210, a bending region 220, and a composite circuit region 230 that are sequentially disposed in a direction away from the display region 100. On a plane perpendicular to the display region, the display panel may include a display substrate 10, a first functional layer disposed on a surface (a light exit surface) of a first side of the display substrate 10, and a second functional layer disposed on a surface (a backlight surface) of a second side of the display substrate 10.

In an exemplary implementation mode, the first functional layer according to the present embodiment may include at least a first adhesive layer 20 disposed on a surface of a first side of the display substrate 10, a polarizing layer 30 disposed on a side of the first adhesive layer 20 away from the display substrate 10, a second adhesive layer 40 disposed on a side of the polarizing layer 30 away from the display substrate 10, and a cover plate layer 50 disposed on a side of the second adhesive layer 40 away from the display substrate 10. Unlike the structure shown in FIG. 7, in the present embodiment, the first adhesive layer 20 and the polarizing layer 30 are provided in the lead region 210, the bending region 220 and the composite circuit region 230, that is, the first adhesive layer 20 and the polarizing layer 30 extend fully from the display region 100 to the composite circuit region 230, and the polarizing layer 30 of the bending region 220 serves as a protective layer for the bending arc, eliminating the protective paste layer in an existing structure. In an exemplary implementation mode, the structure of the second functional layer according to the present embodiment may be substantially the same as that shown in FIG. 7.

In an exemplary implementation mode, the first functional layer of the display panel according to the present embodiment may further include an upper protective layer, or may include a lower protective layer, or may include an upper protective layer and a lower protective layer. In an exemplary implementation mode, the upper protective layer may be disposed on a side of the polarizing layer 30 away from the display substrate, the lower protective layer may be disposed on a side of the first adhesive layer 20 close to the display substrate, and the thickness of the upper protective layer and the lower protective layer may be about 50 to 150 μm, the present disclosure is not limited thereto.

In an exemplary implementation mode, a first shield layer 101 as a bonding shield layer is provided on the display substrate 10 of the lead region 210 according to the present embodiment, and a distance between an edge of a side of the first shield layer 101 close to the display region 100 and a boundary of the display region is less than or equal to 10 μm. For example, the distance between an edge of a side of the first shield layer 101 close to the display region 100 and the boundary of the display region may be 0, that is, the edge of the side of the first shield layer 101 close to the display region 100 substantially overlaps the boundary of the display region, an edge of a side of the first shield layer 101 away from the display region 100 is close to a junction of the lead region 210 and the bending region 220, and an orthographic projection of the first shield layer 101 on the plane of the display substrate at least partially overlaps an orthographic projection of the cover plate shield layer 51 on the plane of the display substrate.

In an exemplary implementation mode, the distance between an edge of a side of the first shield layer 101 away from the display region and the boundary of the display region may be less than the distance between an edge of a side of the second adhesive layer 40 away from the display region and the boundary of the display region, and an orthographic projection of the first shield layer 101 on the plane of the display substrate may be within the range of an orthographic projection of the second adhesive layer 40 on the plane of the display substrate. In an exemplary implementation mode, the width A1 of the first shield layer 101 may be about 350 μm to 450 μm, the width may be a dimension in a direction away from the display region, and the distance between an edge of a side of the first shield layer 101 away from the display region and an edge of a side of the second adhesive layer 40 away from the display region may be about 25 μm to 75 μm. For example, the width of the first shield layer 101 may be about 400 μm, and the distance between an edge of a side of the first shield layer 101 away from the display region and an edge of a side of the second adhesive layer 40 away from the display region may be about 50 μm.

In an exemplary implementation mode, the second adhesive layer 40 may extend close to a boundary of the lead region 210 away from the display region, and the width A2 of the second adhesive layer 40 in the bonding region 200 may be about 400 μm to 500 μm. For example, the width A2 of the second adhesive layer 40 located in the bonding region may be about 450 μm, and the width of the lead region 210 may be about 450 μm.

In an exemplary implementation mode, the distance A3 between an edge of a side of the cover plate shield layer 51 close to the display region and the boundary of the display region may be about 200 μm, so that the width of an overlapped region of an orthographic projection of the first shield layer 101 on the plane of the display substrate and an orthographic projection of the cover plate shield layer 51 on the plane of the display substrate may be about 200 μm.

In an exemplary implementation mode, the first shield layer 101 may be provided in the touch structure layer of the display substrate as a protective layer (TOC) for protecting the touch leads in the touch structure layer. For example, the first shield layer 101 may be disposed on a side of the touch protection layer in the touch structure layer away from the base substrate. As another example, the first shield layer 101 may be arranged in the same layer as the touch protection layer in the touch structure layer, and a portion of the bonding region is blackened. For another example, the first shield layer 101 may be provided on a side of the second touch insulating layer in the touch structure layer away from the base substrate, or the first shield layer 101 may be provided on a side of the first touch insulating layer in the touch structure layer away from the base substrate, which is not limited here in the present disclosure.

In an exemplary implementation mode, a material of the first shield layer 101 may be a black-doped organic material. For example, the first shield layer 101 may be made of an epoxy resin doped with graphite powder. For another example, the first shield layer 101 may be made of an epoxy resin doped with a black paint.

In an exemplary implementation mode, the first shield layer 101 may be prepared and formed using a patterning process. For example, for the first shield layer 101 provided on a side of the touch protection layer in the touch structure layer away from the base substrate, after the touch protection layer is formed, epoxy resin doped with graphite powder or black paint can be coated, and the first shield layer 101 is formed in the lead region 210 through mask exposure and development. For another example, for the first shield layer 101 provided on a side of the touch protection layer in the touch structure layer close to the base substrate, before the touch protection layer is formed, epoxy resin doped with graphite powder or black paint can be coated, the first shield layer 101 is formed in the lead region 210 through mask exposure and development, and then the touch protection layer is formed.

In an exemplary implementation mode, the mask exposure accuracy may be less than about 1 μm. By controlling the accuracy of the mask exposure, the present disclosure can ensure the position accuracy of the first shield layer 101, ensure that a first side of the first shield layer 101 close to the display region is located at the position of the boundary of the display region without affecting the display of the display region, and ensure that an orthographic projection of a second side of the first shield layer 101 away from the display region on the plane of the display substrate and an orthographic projection of the cover plate shield layer 51 on the plane of the display substrate have an overlapped region, thus realizing effective shielding of the bonding region.

In this embodiment, the width of the second sub-region in the existing structure can be effectively reduced by forming the first shield layer 101 in the bonding region using a patterning process and using the polarizing layer 30 as the protective layer. Although the distance between an edge of a side of the cover plate shield layer 51 close to the display region and the boundary of the display region is still 200 μm to 300 μm, since the protective paste layer is eliminated, the influence of the junction region between the polarizing layer and the protective paste layer on the second adhesive layer 40 in the existing structure is eliminated. This allows for effective reduction in the width of the second sub-region or even removal of the second sub-region, so that the width of the bonding region can be effectively reduced.

Furthermore, the present embodiment can effectively solve the problems of poor reflection silver edge, poor light leakage, etc. Because the first shield layer 101 is formed in the bonding region by a patterning process in present embodiment, the first shield layer 101 can not only shield the reflected light of the touch lead, but also shield the reflected light of the power supply line. This completely eliminates any poor reflection silver edge in the bonding region, effectively preventing any poor light leakage or poor imaginary edge in the bonding region, which allows for a clear boundary at the junction between the bonding region and the boundary of the display region, creating a unified black effect in the bonding region.

Furthermore, the present embodiment can also effectively solve the problems such as attachment bubbles. Since the protective paste layer is eliminated in present embodiment, the influence of the junction region between the polarizing layer and the protective paste layer on the second adhesive layer 40 in the existing structure is eliminated, the boundary region of the second adhesive layer 40 is not blocked by the protective paste layer, allowing the adhesive to cover and overflow normally, and attachment bubbles can be effectively prevented. In addition, the second adhesive layer 40 can increase the lap region between the polarizing layer 30 and the cover plate shield layer 51 by means of outward expansion, which, combined with a light shielding structure of the first shield layer 101, can not only eliminate the bubble problem at the boundary of the second adhesive layer to the maximum extent, but also can further reduce the width of the bonding region.

Furthermore, the present embodiment can also simplify the production process. Since the present embodiment uses the polarizing layer 30 as a protective layer and eliminates the protective paste layer, thus not only the problems of uneven coating and glue breakage of the protective paste layer caused by the thinning design of the polarizing layer and the second adhesive layer can be solved, but also a Micro Coating Layer (MCL) process can be reduced, which simplifies the production process, reduce the cost of the process and reduce the cost of the material.

In an exemplary implementation mode, compared with the width of the lead region (the total width of the first sub-region, the second sub-region and the third sub-region) in an existing structure of about 800 to 1100 μm, the scheme of forming a substrate shield layer in the bonding region and using a polarizing layer as a protective layer in the present embodiment can reduce the width of the bonding region to about 500 to 700 μm, for example, the width of the bonding region is about 550 μm, effectively reducing the width of the bonding region.

FIG. 9 is a schematic diagram of a cross-sectional structure of another display panel according to an exemplary embodiment of the present disclosure, illustrating the state of the bonding region after being bent. As shown in FIG. 9, the main structure of the display panel according to the present embodiment may be basically the same as that shown in FIG. 8, the first adhesive layer 20 and the polarizing layer 30 extend fully to the composite circuit region 230, the polarizing layer 30 of the bending region 220 serves as a protective layer, and the protective paste layer of the existing structure is eliminated. The difference is that, the first adhesive layer 20 of the lead region 210 according to the present embodiment is provided with a second shield layer 102 serving as a bonding shield layer.

In an exemplary implementation mode, a first side of the second shield layer 102 close to the display region according to the present embodiment may be located in the lead region 210, a second side of the second shield layer 102 away from the display region extends to the composite circuit region 230 in a direction away from the display region 100, and an orthographic projection of the second shield layer 102 on the plane of the display substrate at least partially overlaps an orthographic projection of the cover plate shield layer 51 on the plane of the display substrate.

In an exemplary implementation mode, the second shield layer 102 is obtained by partially blackening (localized blackening) a portion of the first adhesive layer 20 in the binding region, and the material of the blackened region of the first adhesive layer 20 may be a mixed doping material of acrylic acid and black graphite powder, or a mixed doping material of acrylic acid and black pigment.

In an exemplary implementation mode, the first adhesive layer 20 located in the display region and the second shield layer 102 located in the bonding region may be respectively coated using two coating processes. For example, the first adhesive layer 20 may be coated on the display region first, and then the second shield layer 102 may be coated on the bonding region. Subsequently, the attachment of the polarizing layer 30 may take the boundary between the first adhesive layer 20 and the second shield layer 102 as a basic line to improve the alignment accuracy of the blackened boundary, which is not limited here in the present disclosure.

In an exemplary implementation mode, the distance A4 between an edge of a side of the second shield layer 102 close to the display region and the boundary of the display region may be less than or equal to 100 μm, and the width A2 of the second adhesive layer 40 and the distance A3 between an edge of a side of the cover plate shield layer 51 close to the display region and the boundary of the display region may be substantially the same as the structure shown in FIG. 8, in consideration of the accuracy of the coating of the second shield layer 102.

In an exemplary implementation mode, since the attachment accuracy of the polarizing layer 30 is higher than that of the attachment cover plate layer 50, the scheme according to the present embodiment can effectively improve the shielding effect on the bonding region.

By using blackening on the first adhesive layer and using the polarizing layer as a protective layer in the bonding region, the present embodiment not only can effectively reduce the width of the bonding region, but also can effectively solve problems such as poor reflection silver edge, poor light leakage, and can further effectively solve the problems of attachment bubbles, etc.

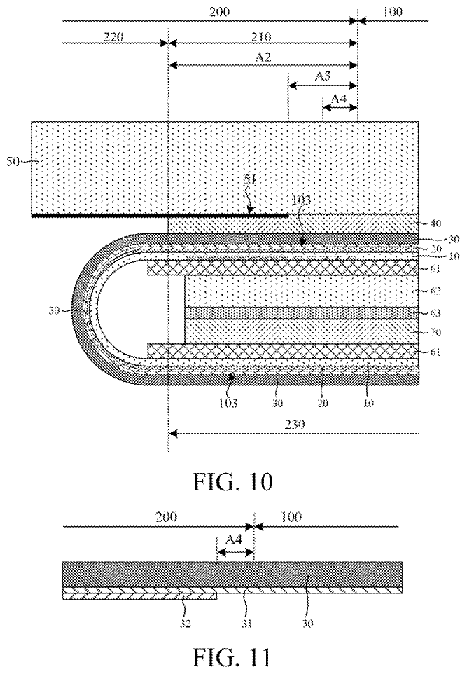

FIG. 10 is a schematic diagram of a cross-sectional structure of yet another display panel according to an exemplary embodiment of the present disclosure, illustrating the state of the bonding region after being bent. As shown in FIG. 10, the main structure of the display panel according to the present embodiment may be basically the same as that shown in FIG. 8, the first adhesive layer 20 and the polarizing layer 30 extend fully to the composite circuit region 230, the polarizing layer 30 of the bending region 220 serves as a protective layer, and the protective paste layer of the existing structure is eliminated. The difference is that the polarizing layer 30 of the lead region 210 according to the present embodiment is provided with a third shield layer 103 serving as a bonding shield layer.

In an exemplary implementation mode, in the present embodiment, a first side of the third shield layer 103 may be located in the lead region 210, a second side of the third shield layer 103 extends to the composite circuit region 230 in a direction away from the display region 100, and an orthographic projection of the third shield layer 103 on the plane of the display substrate at least partially overlaps an orthographic projection of the cover plate shield layer 51 on the plane of the display substrate.

In an exemplary implementation mode, the third shield layer 103 is formed by attaching a shield film on the polarizing layer 30. The shield film may include a first stretch film disposed on a side of the polarizing layer 30 close to the display substrate and a second stretch film disposed on a side of the first stretch film close to the display substrate, or the shield film may include a second stretch film disposed on a side of the polarizing layer 30 close to the display substrate and a first stretch film disposed on a side of the second stretch film close to the display substrate, the stretch direction of the first stretch film intersects the stretch direction of the second stretch film, and an overlapped region of the first stretch film and the second stretch film forms an opaque third shield layer 103 located in the bonding region.

In an exemplary implementation mode, the distance A4 between an edge of a side of the third shield layer 103 close to the display region and the boundary of the display region may be less than or equal to 100 μm, and the width A2 of the second adhesive layer 40 and the distance A3 between an edge of a side of the cover plate shield layer 51 close to the display region and the boundary of the display region may be substantially the same as the structure shown in FIG. 8, in consideration of the attachment accuracy of the third shield layer 103.

FIG. 11 is a schematic diagram of a shield film according to an exemplary embodiment of the present disclosure. As shown in FIG. 11, the shield film may include a first stretch film 31 and a second stretch film 32, the first stretch film 31 may be affixed on a surface of the polarizing layer 30 and may have a shape and size substantially the same as those of the polarizing layer 30. The second stretch film 32 may be affixed on a surface of a side of the first stretch film 31 away from the polarizing layer 30, the length of the second stretch film 32 may be less than the length of the first stretch film 31, the second stretch film 32 may be provided in a region of the polarizing layer 30 corresponding to the bonding region, and the distance A4 between an edge of a side of the second stretch film 32 close to the display region and the boundary of the display region may be less than or equal to 100 μm.

In an exemplary implementation mode, the stretch direction of the first stretch film 31 may be perpendicular to the stretch direction of the second stretch film 32, so that a region where the first stretch film 31 and the second stretch film 32 are stacked forms an opaque region (the third shield layer 103), effectively shielding external light. In this way, after the polarizing layer 30 provided with the first stretch film 31 and the second stretch film 32 is affixed on the display substrate, a light-transmissive region is located in the display region without affecting the display, and an opaque region is located in the bonding region, thus effectively shielding the bonding region. In this embodiment, a dual stretch film method is used to realize light shield, and the scheme design is very ingenious, and because of the high alignment accuracy of the polarizing layer, the influence on the display region is small.

In an exemplary implementation mode, the materials of the first stretch film 31 and the second stretch film 32 may be polyvinyl alcohol (PVA), etc.

By using the dual stretch film and the polarizing layer as the protective layer in the bonding region, the present embodiment not only can effectively reduce the width of the bonding region, but also can effectively solve the problems of poor reflection silver edge, poor light leakage etc., and can further effectively solve the problems of attachment bubbles etc.

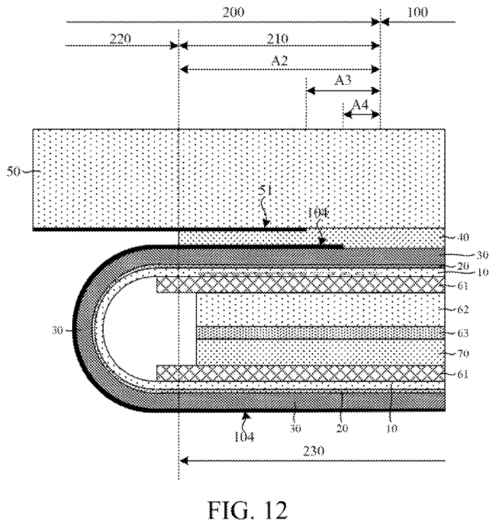

FIG. 12 is a schematic diagram of a cross-sectional structure of yet another display panel according to an exemplary embodiment of the present disclosure, illustrating the state of the bonding region after being bent. As shown in FIG. 12, the main structure of the display panel according to the present embodiment may be basically the same as that shown in FIG. 8, the first adhesive layer 20 and the polarizing layer 30 extend fully to the composite circuit region 230, the polarizing layer 30 of the bending region 220 serves as a protective layer, and the protective paste layer of the existing structure is eliminated. The difference is that, the polarizing layer 30 of the lead region 210 according to the present embodiment is provided with a fourth shield layer 104 serving as a bonding shield layer.

In an exemplary implementation mode, in the present embodiment, a first side of the fourth shield layer 104 may be located in the lead region 210, a second side of the fourth shield layer 104 passes the lead region 210 and the bending region 220 in a direction away from the display region 100 and then enters the composite circuit region 230, an end of the fourth shield layer 104 is connected to a ground pin in the composite circuit region 230, and an orthographic projection of the fourth shield layer 104 on the plane of the display substrate at least partially overlaps an orthographic projection of the cover plate shield layer 51 on the plane of the display substrate.

In an exemplary implementation mode, the fourth shield layer 104 is disposed on a side of the polarizing layer 30 away from the display substrate and is formed by preparing a black pattern layer on the polarizing layer 30. A material of the black pattern layer can be a mixture of graphene and black graphite powder, or a mixture of graphene composite and black graphite powder, and has good adhesion, strong support and strong conductivity.

In an exemplary implementation mode, a black pattern layer on the polarizing layer located in the bonding region may be prepared by screen printing or inkjet printing. For example, by nano inkjet printing, a black graphene solvent is printed, or a mixed solution of acrylic solvent+modifier+black graphene solvent is printed, or a mixed solution of black graphene after oxidation and acrylic solvent is printed. Since graphene is an extremely thin nano-material, it can reach the thickness of nanometer precision, thus minimizing the risk of attachment bubbles.

In an exemplary implementation mode, the distance A4 between an edge of a side of the black pattern layer as the fourth shield layer 104 close to the display region and the boundary of the display region may be less than or equal to 100 μm, and the width A2 of the second adhesive layer 40 and the distance A3 between an edge of a side of the cover plate shield layer 51 close to the display region and the boundary of the display region may be substantially the same as the structure shown in FIG. 8, in consideration of the preparation accuracy of inkjet printing.

In an exemplary implementation mode, since the attachment accuracy of the polarizing layer 30 is higher than that of the bonding cover plate layer, the scheme according to the present embodiment can effectively improve the shielding effect on the bonding region.

In an exemplary implementation mode, the cover plate shield layer 51 may be made of a low-impedance material and the second adhesive layer 40 may be made of a low-impedance material. Since the fourth shield layer 104 made of graphene material has good conductivity, the surface static electricity of the cover plate layer 50 can be transmitted to the ground pin of the bonding region 200 through the low-impedance cover plate shield layer 51, the low-impedance second adhesive layer 40 and the conductive fourth shield layer 104, to form a complete static electricity dissipation path, which conducts away the high voltage on the surface of the cover plate layer, and completely solves the problem of the greening at a low grayscale due to the large voltage.

By preparing a fourth shield layer on the polarizing layer and using the polarizing layer as the protective layer in the bonding region, the present embodiment not only can effectively reduce the width of the bonding region, effectively solve the problems of poor reflection silver edge, poor light leakage, etc., effectively solve the problems of attachment bubbles, etc., but also use the fourth shield layer to form a complete electrostatic dissipation path to conduct away the large voltage on the surface of the cover plate layer, completely solve the problem of the greening at a low grayscale due to the large voltage. The scheme is extremely ingenious and integrates the reduction of the width of the bonding region, light shielding and improvement of static electricity, thus achieving multiple purposes in one go.

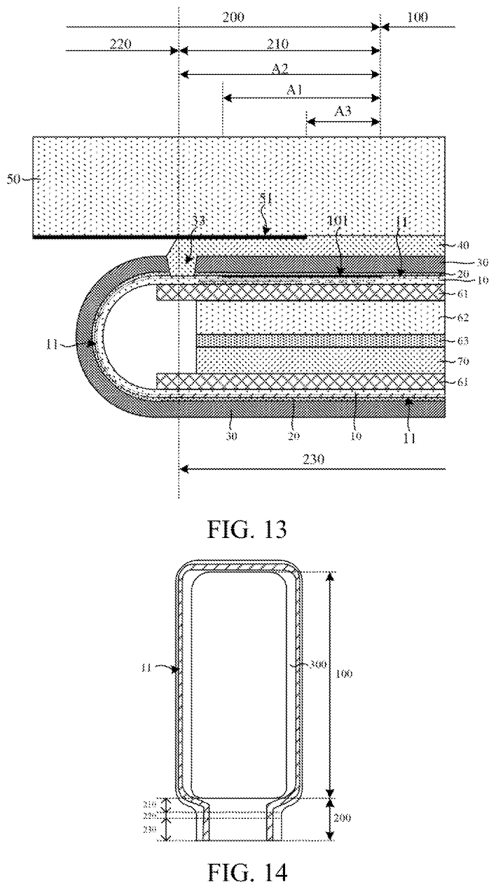

FIG. 13 is a schematic diagram of a cross-sectional structure of yet another display panel according to an exemplary embodiment of the present disclosure, illustrating the state of the bonding region after being bent. As shown in FIG. 13, the main body structure of the display panel according to the present embodiment is basically the same as that of the display panel shown in FIG. 8, the difference is that, the first electrostatic lead is provided in the display substrate of this embodiment, the first electrostatic lead extends from the lead region to the composite circuit region, and the polarizing layer is provided with a connection groove.

In an exemplary implementation mode, in the present embodiment, the first electrostatic lead 11 is provided in the display substrate, and the first electrostatic lead 11 may be provided in the lead region 210, the bending region 220 and the composite circuit region 230, i.e., the first electrostatic lead 11 completely extends to the composite circuit region 230, and the first electrostatic lead 11 is configured to form an electrostatic dissipation path to conduct away a large voltage from the surface of the cover plate layer, and completely solve the problem of the greening at a low grayscale due to the large voltage.

FIG. 14 is a schematic diagram of a planar structure of a first electrostatic lead according to an exemplary embodiment of the present disclosure. As shown in FIG. 14, the first electrostatic lead 11 may be provided in the bonding region 200 and the bezel region 300, the first electrostatic lead 11 extends along the bezel region 300, the first electrostatic lead 11 extended to the bonding region 200 passes through the lead region 210 and the bending region 220 and then enters the composite circuit region 230, and an end of the first electrostatic lead 11 is connected to the ground pin in the composite circuit region 230.

In an exemplary implementation mode, the first electrostatic lead 11 and the touch lead of the display region may be disposed on the same layer and are synchronously formed through a same patterning process.

In an exemplary implementation mode, a connection groove 33 on the polarizing layer 30 may be provided at a junction region between the lead region 210 and the bending region 220, and the polarizing layer 30 and the first adhesive layer 20 in the connection groove 33 are completely removed, to expose the surface of the first electrostatic lead 11. The second adhesive layer 40 extends to the junction region between the lead region 210 and the bending region 220 such that the second adhesive layer 40 fills the connection groove 33 and the second adhesive layer 40 is lapped with the first electrostatic lead 11.

In an exemplary implementation mode, the cover plate shield layer 51 may be made of a low-impedance material and the second adhesive layer 40 may be made of a low-impedance material. For example, the cover plate shield layer 51 may be made of a nano graphene material. In this way, the surface static electricity of the cover plate layer 50 can be transmitted to the ground pin of the bonding region 200 through the low-impedance cover plate shield layer 51, the low-impedance second adhesive layer 40 and the first static electricity lead 11, to form a complete electrostatic dissipation path to conduct away the large voltage on the surface of the cover plate layer, completely solve the problem of the greening at a low grayscale due to the large voltage.

In an exemplary implementation mode, the first electrostatic lead 11 with a wide line width may be provided so that the first electrostatic lead 11 exposed in the connection groove 33 will not be subject to corrosion problems at high temperatures and high humidity.

In an exemplary implementation mode, an edge of a side of the connection groove 33 close to the display region may be set flush with an edge of a side of the second adhesive layer 40 away from the display region, and the adhesive overflow at an edge of the second adhesive layer 40 is used to cause the second adhesive layer 40 to fill the connection groove 33, so that the electrical connection between the second adhesive layer 40 and the first electrostatic lead 11 can be ensured within a tolerance range even when the attachment of the second adhesive layer 40 is offset.

In an exemplary implementation mode, the width of the connection groove 33 may be about 150 to 250 μm. For example, the width of the connection groove 33 may be about 200 μm. In an exemplary implementation mode, the center line of the connection groove 33 may be set to overlap a boundary of the lead region 210 away from the display region (a boundary of the bending region 220 close to the display region). For example, the distance between a side wall on a side of the connection groove 33 close to the display region and the boundary of the lead region 210 away from the display region may be about 100 μm, and the distance between a side wall on a side of the connection groove 33 away from the display region and the boundary of the lead region 210 away from the display region may be about 100 μm.

In an exemplary implementation mode, an orthographic projection of the connection groove 33 on the plane of the display substrate may at least partially overlap an orthographic projection of the first shield layer 101 on the plane of the display substrate.

The scheme according to the present embodiment not only can effectively reduce the width of the bonding region, effectively solve poor reflection silver edge and poor light leakage, and effectively solve the problems of attachment bubbles, etc., but also forms a complete electrostatic dissipation path by arranging a first electrostatic lead in the display substrate and setting a connection groove in the polarizing layer, to conduct away the large voltage on the surface of the cover plate layer, completely solve the problem of the greening at a low grayscale due to the large voltage.

In an exemplary implementation mode, the scheme according to the present embodiment in which the first electrostatic lead extending to the composite circuit region is provided in the display substrate and the polarizing layer is provided with a connection groove can be combined with the scheme in which the first adhesive layer is blackened as shown in FIG. 9 or with the scheme of the dual stretch film as shown in FIG. 10. The combined scheme can effectively reduce the width of the bonding region, effectively solve the problems of poor reflective silver edge and poor light leakage, effectively solve the problem of attachment bubbles etc., and effectively solve the problem of the greening at a low grayscale due to the large voltage.

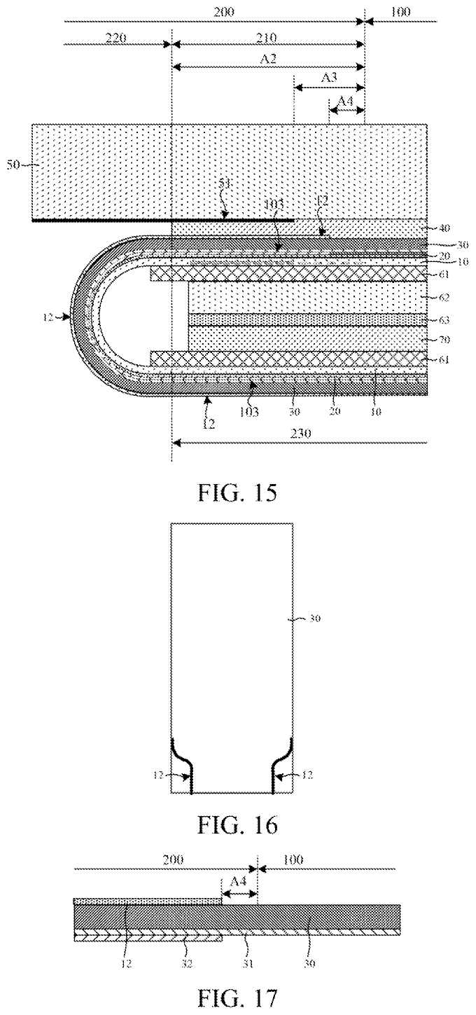

FIG. 15 is a schematic diagram of a cross-sectional structure of yet another display panel according to an exemplary embodiment of the present disclosure, illustrating the state of the bonding region after being bent. As shown in FIG. 15, the main body structure of the display panel according to the present embodiment is basically the same as that of the display panel shown in FIG. 10, the difference is that, a second electrostatic lead is further provided on the polarizing layer of this embodiment, and the second electrostatic lead extends to the composite circuit region.

In an exemplary implementation mode, the polarizing layer 30 of this embodiment is provided with a second electrostatic lead 12, which may be provided in the lead region 210, the bending region 220 and the composite circuit region 230, i.e., the second electrostatic lead 12 extends completely from the lead region 210 to the composite circuit region 230, an end of the second electrostatic lead 12 is connected with the ground pin in the composite circuit region, and the second electrostatic lead 12 is configured to form an electrostatic dissipation path to conduct away the large voltage on the surface of the cover plate layer, completely solve the problem of the greening at a low grayscale due to the large voltage.

In an exemplary implementation mode, the second electrostatic lead 12 is realized by preparing a conductive lead on the polarizing layer 30 located in the bonding region, and the material of the conductive lead may be graphene or a graphene composite, and has good adhesion, strong support and strong conductivity.

In an exemplary implementation mode, the second electrostatic lead 12 may be prepared by screen printing or inkjet printing. For example, graphene solvent is printed by nano inkjet printing, or a mixed solution of acrylic solvent+modifier+graphene solvent is printed, or a mixed solution of graphene after oxidation and acrylic solvent is printed. Since graphene is an extremely thin nano-material, it can reach the thickness of nanometer precision, thus minimizing the risk of attachment bubbles.

In an exemplary implementation mode, the distance A4 between an edge of a side of the second electrostatic lead 12 close to the display region side and the boundary of the display region may be less than or equal to 100 μm, that is, an edge of a side of the second electrostatic lead 12 close to the display region side is flush with an edge of a side of the second stretch film 32 close to the display region, in consideration of the preparation accuracy of ink jet printing.

In an exemplary implementation mode, the cover plate shield layer 51 may be made of a low-impedance material and the second adhesive layer 40 may be made of a low-impedance material. Since the second electrostatic lead 12 made of graphene material has good conductivity, the surface static electricity of the cover plate layer 50 can be transmitted to the ground pin of the bonding region 200 through the low-impedance cover plate shield layer 51, the low-impedance second adhesive layer 40 and the second electrostatic lead 12, to form a complete electrostatic dissipation path to conduct away the large voltage on the surface of the cover plate layer, completely solving the problem of the greening at a low grayscale due to the large voltage.

FIG. 16 is a schematic diagram of a planar structure of a second electrostatic lead according to an exemplary embodiment of the present disclosure, and FIG. 17 is a schematic diagram of a cross-sectional structure of a second electrostatic lead according to an exemplary embodiment of the present disclosure. As shown in FIG. 16, the second electrostatic lead 12 may be formed on the polarizing layer 30 by means of screen printing or ink jet printing with graphene solvent. The second electrostatic lead 12 may be provided in corresponding regions of the polarizing layer 30 and the bonding region 200. The shape of the second electrostatic lead 12 may be substantially similar to the contour of the outline of the bonding region 200. The second electrostatic lead 12 passes through the lead region and the bending region and then enters the composite circuit region. An end of the second electrostatic lead 12 is connected with the ground pin in the composite circuit region. As shown in FIG. 17, the first stretch film 31 and the second stretch film 32 may be provided on a surface of side of the polarizing layer 30 close to the display substrate to effectively shield external light, and the second electrostatic lead 12 may be provided a surface of side of the polarizing layer 30 away from the display substrate to form an electrostatic dissipation path.

The scheme according to the present embodiment not only can effectively reduce the width of the bonding region, effectively solve poor reflection silver edge and poor light leakage, and effectively solve the problems of attachment bubbles, etc., but also forms a complete electrostatic dissipation path by arranging a second electrostatic lead on the polarizing layer, to conduct away the large voltage on the surface of the cover plate layer, completely solve the problem of the greening at a low grayscale due to the large voltage.

In an exemplary implementation mode, the scheme according to the present embodiment in which the second electrostatic lead is provided on the polarizing layer can be combined with the scheme in which the first shield layer is provided on the display substrate shown in FIG. 8, or can be combined with the scheme in which the first adhesive layer is blackened as shown in FIG. 9. The combined scheme can effectively reduce the width of the bonding region, effectively solve the problems of poor reflective silver edge and poor light leakage, effectively solve the problem of attachment bubbles etc., and effectively solve the problem of the greening at a low grayscale due to the large voltage.

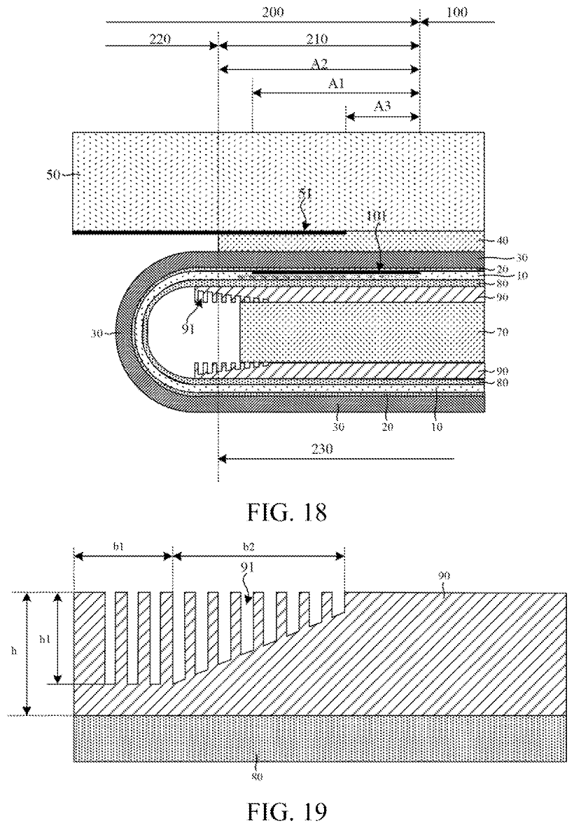

FIG. 18 is a schematic diagram of a cross-sectional structure of yet another display panel according to an exemplary embodiment of the present disclosure, illustrating the state of the bonding region after being bent. As shown in FIG. 18, the main body structure of the display panel according to the present embodiment is basically the same as that of the display panel shown in FIG. 8, the difference is that, a reinforcing layer and a third adhesive layer are used in the second functional layer of the display panel according to the present embodiment to replace the back film layer, the first heat dissipation layer and the second heat dissipation layer of the existing structure.

In an exemplary implementation mode, the structure of the first functional layer in the display panel according to the present embodiment may be substantially the same as the structure of the first functional layer shown in FIG. 8, the first shield layer 101 is disposed on the display substrate 10, and the first adhesive layer 20 and the polarizing layer 30 extend fully to the composite circuit region 230.

In an exemplary implementation mode, the second functional layer in the display panel according to the present embodiment may include at least a third adhesive layer 80 disposed on a surface of a second side of the display substrate 10, a reinforcing layer 90 disposed on a side of the third adhesive layer 80 away from the display substrate 10, and a spacer 70 disposed on a side of the reinforcing layer 90 away from the display substrate 10. The third adhesive layer 80 is configured to attach the reinforcing layer 90 to a surface of a second side of the display substrate 10 and may extend from the display region to the composite circuit region 230 through the lead region 210 and the bending region 220. In an exemplary implementation mode, the third adhesive layer 80 may be made of pressure sensitive adhesive. The spacer 70 is configured to be attached to the reinforcing layer 90 of the lead region 210 and the reinforcing layer 90 of the composite circuit region 230 respectively and may extend from the display region 100 to the lead region 210.

In an exemplary implementation mode, the reinforcing layer 90 may be disposed in the lead region 210 and the composite circuit region 230. The reinforcing layer 90 located in the lead region 210 and the composite circuit region 230 is provided with a plurality of first reinforcing grooves 91 that may be disposed at intervals in a direction away from the display region, the groove depths of the plurality of first reinforcing grooves 91 of the lead region 210 may gradually increase in a direction away from the display region, and the groove depths of the plurality of first reinforcing grooves 91 of the composite circuit region 230 may gradually decrease in a direction away from the display region, i.e., the groove depths of the plurality of first reinforcing grooves 91 of the lead region 210 and the composite circuit region 230 gradually increase in a direction close to the bending region 220, and the plurality of first reinforcing grooves 91 are configured such that the reinforcing layer 90 is adaptively bent in an edge region of the bending arc.

In an exemplary implementation mode, the material of the reinforcing layer 90 may be stainless steel (SUS), which has strong support performance, can meet support requirements, can avoid the problem of insufficient support due to thinning of the back film layer or the use of an optical back film material, can avoid cracks on edges of the bending region to the maximum extent, and avoid the risk of bright lines. In addition, the reinforcing layer 90 of the stainless steel material has better heat dissipation performance, and therefore, compared with existing structures of the back film layer and the heat dissipation layer, the scheme according to the present embodiment can enhance the heat dissipation effect of the display substrate.

In an exemplary implementation mode, the third adhesive layer 80 is continuously disposed in the lead region 210, the bending region 220, and the composite circuit region 230, and a support layer is formed on the back of the display substrate, which is equivalent to adding an organic support layer, which may further reduce the risk of fracture in the bending region.

In an exemplary implementation mode, the second functional layer of the display panel according to the present embodiment may further include an upper protective layer, or may include a lower protective layer, or may include an upper protective layer and a lower protective layer. In an exemplary implementation mode, the upper protective layer may be disposed on a side of the reinforcing layer 90 away from the display substrate, the lower protective layer may be disposed on a side of the third adhesive layer 80 close to the display substrate, and the thickness of the upper protective layer and the lower protective layer may be about 50 to 150 μm, which is not limited here in the present disclosure.

FIG. 19 is a schematic structural diagram of a reinforcing layer according to an exemplary embodiment of the present disclosure. The plurality of first reinforcing grooves 91 on the reinforcing layer 90 have a groove depth gradient structure, which can completely circumvent the display substrate from being subjected to sharp stresses. As shown in FIG. 19, the reinforcing layer 90 may at least include an equal groove depth region b1 and a variable groove depth region b1, the equal groove depth region b1 is located on a side of the variable groove depth region b1 close to the bending region 220, the groove depths of that plurality of first reinforcing groove 91 in the equal groove depth region b1 are equal, the groove depths of the plurality of first reinforcing grooves 91 in the variable groove depth region b1 gradually increase in a direction close to the bending region 220.

In an exemplary implementation mode, the width of the equal groove depth region b1 may be about 80 to 120 μm, the width of the variable groove depth region b1 may be about 180 to 250 μm, the width of the first reinforcing groove 91 may be about 10 to 20 μm, the spacing between adjacent first reinforcing grooves 91 may be about 10 to 20 μm, and the quantity of unilateral first reinforcing grooves 91 may be determined according to the support condition. For example, the width of the first reinforcing groove 91 may be about 15 μm and the spacing between adjacent first reinforcing grooves 91 may be about 15 μm.

In an exemplary implementation mode, the depth hi of the first reinforcing groove 91 in the equal groove depth region b1 may be about 70% to 80% of the thickness h of the reinforcing layer 90.

In an exemplary implementation mode, the plurality of first reinforcing grooves 91 of the lead region 210 and the plurality of first reinforcing grooves 91 of the composite circuit region 230 may be disposed symmetrically with respect to a bending groove on the display substrate, and an edge of the reinforcing layer 90 may be flush with an edge of the bending groove on the display substrate.

In an exemplary implementation mode, the plurality of first reinforcing grooves 91 on the reinforcing layer 90 may be formed using a patterning process (mask exposure, development and etching processes). Since the reinforcing layer 90 has extremely strong support performance for the bending arc, and the process precision of preparing the first reinforcing groove 91 has less influence on the support performance, the present embodiment has low process requirements, and can broaden the process margin and reduce the process requirements.

In an exemplary implementation mode, the thickness of the third adhesive layer 80 may be about 15 to 25 μm, and the thickness of the reinforcing layer 90 may be about 80 to 100 μm.

Compared with a structure in which the total thickness of the back film layer and the heat dissipation layer is about 230-330 μm and the total thickness of the display panel is about 280-480 μm, the total thickness of the third adhesive layer and the reinforcing layer in the present embodiment is about 95-125 μm and the total thickness of the display panel is about 195-265 μm, the overall thickness is reduced by 1/2, the problem of larger thickness in the existing structure is effectively solved, which is beneficial to achieving the slimming of the display panel.

The scheme according to the present embodiment not only can effectively reduce the width of the bonding region, effectively solve poor reflection silver edge and poor light leakage, and effectively solve the problems of attachment bubbles, etc., but also can effectively reduce the overall thickness by replacing the back film layer and the heat dissipation layer of the existing structure with a reinforcing layer, can adapt to a smaller bending radius, and can further reduce the width of the bonding region.

In an exemplary implementation mode, the scheme according to the present embodiment in which the reinforcing layer is used can be combined with the scheme in which the first adhesive layer is blackened as shown in FIG. 9, or combined with the scheme of the dual stretch film as shown in FIG. 10, or combined with the scheme in which the bonding shield layer is prepared on the polarizing layer as shown in FIG. 12, or combined with the scheme in which the first electrostatic lead is provided on the display substrate as shown in FIG. 13, or combined with the scheme in which the second electrostatic lead is provided on the polarizer as shown in FIG. 15, the combined scheme can not only effectively reduce the width of the bonding region, effectively solve the problems of poor reflective silver edge and poor light leakage, effectively solve the problem of attachment bubbles, etc., and effectively solve the problem of the greening at a low grayscale due to the large voltage, but also can effectively improve the support, effectively reduce the overall thickness, which is beneficial to achieving the slimming of the display panel.

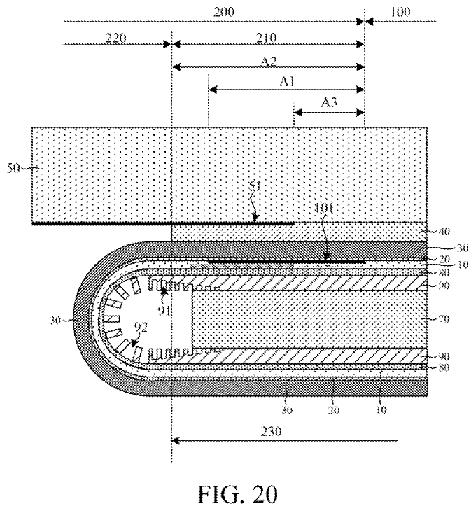

FIG. 20 is a schematic diagram of a cross-sectional structure of yet another display panel according to an exemplary embodiment of the present disclosure, illustrating the state of the bonding region after being bent. As shown in FIG. 20, the main body structure of the display panel according to the present embodiment is substantially the same as that of the display panel shown in FIG. 18, the difference is that, the reinforcing layer 90 in the present embodiment extends from the lead region 210 to the composite circuit region 230.

In an exemplary implementation mode, in the present embodiment, the reinforcing layers 90 are provided in the lead region 210, the bending region 220 and the composite circuit region 230, respectively, the reinforcing layers 90 located in the lead region 210 and the composite circuit region 230 are provided with a plurality of first reinforcing grooves 91, and the reinforcing layer 90 located in the bending region 220 is provided with a plurality of second reinforcing grooves 92. In an exemplary implementation mode, the plurality of first reinforcing grooves 91 may be disposed at intervals in a direction away from the display region, and the groove depth of the first reinforcing groove 91 may be gradually increased in a direction close to the bending region 220, and the groove depth of the first reinforcing grooves 91 is less than the thickness of the reinforcing layer 90, that is, the plurality of first reinforcing grooves 91 are blind grooves. The plurality of second reinforcing grooves 92 may be disposed at intervals along the bending region 220 and the groove depth of the second reinforcing grooves 92 is equal to the thickness of the reinforcing layer 90, i.e., the plurality of first reinforcing grooves 91 are through grooves.

In an exemplary implementation mode, the plurality of second reinforcing grooves 92 provided on the reinforcing layer 90 can realize adaptive force attachment of the reinforcing layer on the bending arc, the attachment pressure is uniform, and the adaptively released attachment pressure can not only avoid the compression of the reinforcing layer 90 on the back of the display substrate, avoid the problems of edge crushing, edge warping and edge cracks, etc., and thoroughly improve the problem of bright lines caused by cracks, but can also adapt to a smaller bending radius and can further reduce the width of the bonding region.

In an exemplary implementation mode, the width of the second reinforcing groove 92 may be about 10 to 20 μm, the spacing between adjacent second reinforcing grooves 92 may be about 10 to 20 μm, and the quantity of the second reinforcing grooves 92 in the bending region 220 may be determined according to the size of the bending arc. For example, the width of the second reinforcing groove 92 may be about 15 μm and the spacing between adjacent second reinforcing grooves 92 may be about 15 μm.

In an exemplary implementation mode, the plurality of second reinforcing grooves 92 of the bending region 220 may be symmetrical with respect to the centerline of the bending groove on the display substrate.

In an exemplary implementation mode, the plurality of first reinforcing grooves 91 and second reinforcing grooves 92 on the reinforcing layer 90 may be formed synchronously using a patterning process.

The scheme according to the present embodiment not only can effectively reduce the width of the bonding region, effectively solve poor reflection silver edge and poor light leakage, and effectively solve the problems of attachment bubbles etc., but also can effectively reduce the overall thickness by replacing the back film layer and the heat dissipation layer of the existing structure with a reinforcing layer. Moreover, with a plurality of first reinforcing grooves and a plurality of second reinforcing grooves provided on the reinforcing layer, the scheme according to the present embodiment can not only avoid the compression on the back of the display substrate, avoid the problems of edge crushing, edge warping and edge cracks, etc., and thoroughly improve the problem of bright lines caused by cracks, but can also adapt to a smaller bending radius and can further reduce the width of the bonding region.

In an exemplary implementation mode, the scheme according to the present embodiment in which the first reinforcing groove and the second reinforcing groove are provided on the reinforcing layer can be respectively combined with the scheme in which the first adhesive layer is blackened as shown in FIG. 9, the scheme of the dual stretch film as shown in FIG. 10, the scheme in which the bonding shield layer is prepared on the polarizing layer as shown in FIG. 12, the scheme in which the first electrostatic lead is provided on the display substrate as shown in FIG. 13, and the scheme in which the second electrostatic lead is provided on the polarizer as shown in FIG. 15. The combined scheme can not only effectively reduce the width of the bonding region, effectively solve the problems of poor reflective silver edge and poor light leakage, effectively solve the problem of attachment bubbles etc., and effectively solve the problem of the greening at a low grayscale due to the large voltage, but also can effectively improve the support, effectively reduce the overall thickness, which is beneficial to achieving the slimming of the display panel.

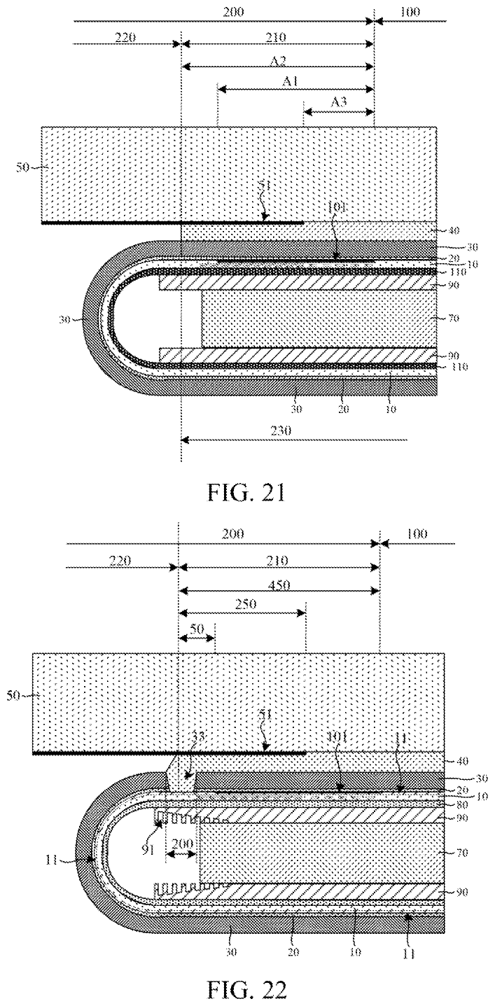

FIG. 21 is a schematic diagram of a cross-sectional structure of yet another display panel according to an exemplary embodiment of the present disclosure, illustrating the state of the bonding region after being bent. As shown in FIG. 21, the main body structure of the display panel according to the present embodiment is basically the same as that of the display panel shown in FIG. 8, the difference is that, a reinforcing layer and a conductive paste layer are used in the second functional layer of the display panel according to the present embodiment to replace the back film layer, the first heat dissipation layer and the second heat dissipation layer of the existing structure.

In an exemplary implementation mode, the structure of the first functional layer in the display panel according to the present embodiment may be substantially the same as the structure of the first functional layer shown in FIG. 8, the first shield layer 101 is disposed on the display substrate 10, and the first adhesive layer 20 and the polarizing layer 30 extend fully to the composite circuit region 230.

In an exemplary implementation mode, the second functional layer in the display panel according to the present embodiment may include at least a conductive paste layer 110 disposed on a surface of a second side of the display substrate 10, a reinforcing layer 90 disposed on a side of the conductive paste layer 110 away from the display substrate 10, and a spacer 70 disposed on a side of the reinforcing layer 90 away from the display substrate 10.

In an exemplary implementation mode, the conductive paste layer 110 may extend from the display region to the composite circuit region 230 through the lead region 210 and the bending region 220, and an end of the conductive paste layer 1101 is connected to the ground pin in the composite circuit region 230. The conductive paste layer 110 is configured to attach the reinforcing layer 90 to a surface of a second side of the display substrate 10 on the one hand, and form an electrostatic dissipation path on the other hand to conduct away the large voltage on the surface of the cover plate layer, completely solve the problem of the greening at a low grayscale due to the large voltage.

In an exemplary implementation mode, the reinforcing layer 90 may be disposed in the lead region 210 and the composite circuit region 230, may have an integral structure, i.e., the reinforcing layer 90 is not provided with grooves.

In an exemplary implementation mode, the material of the reinforcing layer 90 may be stainless steel (SUS), which has strong support performance, and the material of the conductive paste layer 110 may be graphene or a graphene composite, and has good adhesion, strong support and strong conductivity.

In an exemplary implementation mode, the conductive paste layer 110 is continuously disposed in the lead region 210, the bending region 220 and the composite circuit region 230 to form a support layer on a back of the display substrate. Since graphene material has characteristics such as extremely high strength, bending toughness and adhesive layer viscosity, it can ensure the stress release of the bending arc in the case of “over-tension” or “under-tension”, and realize self-adaptation to the two cases. Since graphene material has strong electrical conductivity, it can realize the dissipation of high static voltage.

The scheme according to the present embodiment not only can effectively reduce the width of the bonding region, effectively solve poor reflection silver edge and poor light leakage, and effectively solve the problems of attachment bubbles, etc., but also can effectively reduce the overall thickness by replacing the back film layer and the heat dissipation layer of the existing structure with a reinforcing layer and a conductive paste layer, and can ensure the stress release of the bending arc in the case of “over-tension” or “under-tension” through the conductive paste layer of graphene material, realize self-adaptation to the two cases, and realize the dissipation of high static voltage. Compared with the schemes shown in FIGS. 18 and 20, the present embodiment reduces the grooving process on the reinforcing layer and simplifies the process.

In an exemplary implementation mode, the scheme of the reinforcing layer and the conductive paste layer according to the present embodiment can be respectively combined with the scheme in which the first adhesive layer is blackened as shown in FIG. 9, the scheme of the dual stretch film as shown in FIG. 10, the scheme in which the bonding shield layer is prepared on the polarizing layer as shown in FIG. 12, the scheme in which the first electrostatic lead is provided on the display substrate as shown in FIG. 13, and the scheme in which the second electrostatic lead is provided on the polarizer as shown in FIG. 15. The combined scheme can not only effectively reduce the width of the bonding region, effectively solve the problems of poor reflective silver edge and poor light leakage, effectively solve the problem of attachment bubbles etc., and effectively solve the problem of the greening at a low grayscale due to the large voltage, but also can effectively improve the support, effectively reduce the overall thickness, which is beneficial to achieving the slimming of the display panel.

FIG. 22 is a schematic diagram of a cross-sectional structure of yet another display panel according to an exemplary embodiment of the present disclosure, illustrating the state of the bonding region after being bent. As shown in FIG. 22, on a plane perpendicular to the display region, the display panel may include a display substrate 10, a first functional layer disposed on a surface of a first side of the display substrate 10, and a second functional layer disposed on a surface of a second side of the display substrate 10.

In an exemplary implementation mode, the first functional layer may include at least a first adhesive layer 20 disposed on a surface of a first side of the display substrate 10, a polarizing layer 30 disposed on a side of the first adhesive layer 20 away from the display substrate 10, a second adhesive layer 40 disposed on a side of the polarizing layer 30 away from the display substrate 10, and a cover plate layer 50 disposed on a side of the second adhesive layer 40 away from the display substrate 10. The first adhesive layer 20 and the polarizing layer 30 extend completely from the display region 100 to the composite circuit region 230. The display substrate 10 is provided with a first shield layer 101 and a first electrostatic lead 11 as a bonding shield layer, and the polarizing layer 30 is provided with a connection groove 33, the second adhesive layer 40 fills the connection groove 33, and the second adhesive layer 40 is lapped with the first electrostatic lead 11.

In an exemplary implementation mode, the second functional layer may include at least a third adhesive layer 80 disposed on a surface of a second side of the display substrate 10, a reinforcing layer 90 disposed on a side of the third adhesive layer 80 away from the display substrate 10, and a spacer 70 disposed on a side of the reinforcing layer 90 away from the display substrate 10, the third adhesive layer 80 may extend from the display region to the composite circuit region 230 through the lead region 210 and the bending region 220, the reinforcing layer 90 may be disposed in the lead region 210 and the composite circuit region 230, and the reinforcing layer 90 located in the lead region 210 and the composite circuit region 230 is provided with a plurality of first reinforcing grooves 91.

In an exemplary implementation mode, the distance between an edge of a side of the first shield layer 101 away from the display region and a boundary of the lead region may be about 50 μm, an edge of a side of the second adhesive layer 40 away from the display region may be flush with the boundary of the lead region, the distance between an edge of a side of the second adhesive layer 40 away from the display region and the boundary of the display region may be about 450 μm, the distance between an edge of a side of the second adhesive layer 40 away from the display region and an edge of a side of the cover plate shield layer 51 close to the display region may be about 250 μm, the width of the bending groove on the display substrate may be about 200 μm, the width of the connection groove 33 on the polarizer 30 may be about 200 μm, the distance between an edge of a side of the second adhesive layer 40 away from the display region and a groove edge of the connection groove 33 may be about 100 μm, and the boundary of the bending groove can be flush with the edge of the reinforcing layer.

As can be seen from the above embodiments, the display panel provided by the exemplary embodiment of the present disclosure, through a combination of technical means such as providing the bonding shield layer in the bonding region, providing the electrostatic lead in the bonding region and adopting the reinforcing layer, can not only effectively reduce the width of the bonding region, effectively solve the problems of poor reflective silver edge and poor light leakage, effectively solve the problem of attachment bubbles etc., and effectively solve the problem of the greening at a low grayscale due to the large voltage, but also can effectively improve the support, effectively reduce the overall thickness, which is beneficial to achieving the slimming of the display panel, can further simplify the production process, reduce the cost of the process and reduce the cost of the material. The preparation of the display panel according to the present disclosure does not need to change the existing process flow or process equipment, has little change on the existing process, can be well compatible with the existing preparation process, and has high process realizability and strong practicability.

The scheme of the foregoing embodiment of the present disclosure and the features in the scheme of the embodiment may be arbitrarily combined with each other, which is not limited here in the present disclosure.

In an exemplary implementation, the display panel of the present disclosure may be applied to a display panel with a pixel drive circuit, such as an OLED, a Quantum dot display (QLED), a Light Emitting Diode display (Micro LED or Mini LED), or a Quantum Dot Light Emitting Diode display (QDLED), which is not limited here in the present disclosure.

An exemplary embodiment of the present disclosure further provides a method for preparing a display panel to prepare the display panel of the foregoing exemplary embodiments.

In an exemplary implementation mode, the display panel includes a display region and a bonding region located on a side of the display region, wherein the bonding region comprises a lead region, a bending region and a composite circuit region arranged sequentially in a direction away from the display region, the bending region is configured to flip the composite circuit region to a back of the display region by being bent; the preparation method may include: forming a first functional layer and a second functional layer on a light exit side surface and a backlight side surface of a display substrate, respectively; the first functional layer of the bonding region at least comprises a first adhesive layer, a polarizing layer disposed on a side of the first adhesive layer away from the display substrate, a second adhesive layer disposed on a side of the polarizing layer away from the display substrate, and a cover plate layer disposed on a side of the second adhesive layer away from the display substrate; the first adhesive layer and the polarizing layer are disposed in the lead region, the bending region and the composite circuit region, a side of the cover plate layer close to the display substrate is provided with a cover plate shield layer, and at least one of the display substrate, the first adhesive layer and the polarizing layer is provided with a bonding shield layer, the distance between an edge of a side of the bonding shield layer close to the display region and the boundary of the display region is less than the distance between an edge of a side of the cover plate shield layer close to the display region and the boundary of the display region, and the boundary of the display region is an edge of a side of the display region close to the bonding region.

An exemplary embodiment of the present disclosure also provides a display device, including the foregoing display panel. The display device in the exemplary embodiment of the present disclosure may be any product or component with a display function, such as a mobile phone, a tablet computer, a television, a display, a laptop computer, a digital photo frame, or a navigator.

Although the implementations of the present disclosure are disclosed above, the contents are only implementations adopted to easily understand the present disclosure and not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display panel comprising a display region and a bonding region located on a side of the display region, wherein the bonding region comprises a lead region, a bending region and a composite circuit region arranged sequentially in a direction away from the display region, the bending region is configured to flip the composite circuit region to a back of the display region by being bent; in a plane perpendicular to the display panel, the bonding region comprises a display substrate, a first functional layer on a light exit side surface of the display substrate, and a second functional layer on a backlight side surface of the display substrate, the first functional layer at least comprises a first adhesive layer, a polarizing layer disposed on a side of the first adhesive layer away from the display substrate, a second adhesive layer disposed on a side of the polarizing layer away from the display substrate, and a cover plate layer disposed on a side of the second adhesive layer away from the display substrate; the first adhesive layer and the polarizing layer are arranged in the lead region, the bending region and the composite circuit region, a side of the cover plate layer close to the display substrate is provided with a cover plate shield layer, and at least one of the display substrate, the first adhesive layer and the polarizing layer is provided with a bonding shield layer, a distance between an edge of a side of the bonding shield layer close to the display region and a boundary of the display region is less than a distance between an edge of a side of the cover plate shield layer close to the display region and the boundary of the display region, and the boundary of the display region is an edge of a side of the display region close to the bonding region.

2. The display panel according to claim 1, wherein the bonding shield layer comprises a first shield layer disposed in the display substrate, a distance between an edge of a side of the first shield layer close to the display region and the boundary of the display region is less than or equal to 10 μm, and an orthographic projection of the first shield layer on a plane of the display substrate at least partially overlaps an orthographic projection of the cover plate shield layer on the plane of the display substrate.

3. The display panel according to claim 2, wherein, in a plane perpendicular to the display panel, the display substrate comprises a drive circuit layer disposed on a base substrate, a light emitting structure layer disposed on a side of the drive circuit layer away from the base substrate, an encapsulation structure layer disposed on a side of the light emitting structure layer away from the base substrate, and a touch structure layer disposed on a side of the encapsulation structure layer away from the base substrate, the first shield layer is disposed in the touch structure layer.

4. (canceled)

5. The display panel according to claim 2, wherein the first shield layer has a width of 350 to 450 μm, the width is a dimension along a direction away from the display region, and an orthographic projection of the first shield layer on the plane of the display substrate is within a range of an orthographic projection of the second adhesive layer on the plane of the display substrate.

6. The display panel according to claim 1, wherein the bonding shield layer comprises a second shield layer disposed in the first adhesive layer, a distance between an edge of a side of the second shield layer close to the display region and the boundary of the display region is less than or equal to 100 μm, and an orthographic projection of the second shield layer on a plane of the display substrate at least partially overlaps an orthographic projection of the cover plate shield layer on the plane of the display substrate.

7. The display panel according to claim 6, wherein the second shield layer is formed by blackening a portion of the first adhesive layer located in the bonding region, and the second shield layer extends from the lead region to the composite circuit region.

8. The display panel according to claim 1, wherein the bonding shield layer comprises a third shield layer and/or a fourth shield layer disposed on the polarizing layer, a distance between an edge of a side of the third shield layer or the fourth shield layer close to the display region and the boundary of the display region is less than or equal to 100 μm, and an orthographic projection of the third shield layer or the fourth shield layer on a plane of the display substrate at least partially overlaps an orthographic projection of the cover plate shield layer on the plane of the display substrate.

9. The display panel according to claim 8, wherein the first functional layer further comprises a first stretch film disposed on a side of the polarizing layer close to the display substrate and a second stretch film disposed on a side of the first stretch film close to the display substrate, a stretch direction of the first stretch film intersects a stretch direction of the second stretch film, and an overlapped region of the first stretch film and the second stretch film forms an opaque third shield layer located in the bonding region.

10. The display panel according to claim 8, wherein the fourth shield layer is disposed on a side of the polarizing layer away from the display substrate, and is prepared and formed on the polarizing layer located in the bonding region by screen printing or inkjet printing.

11. (canceled)

12. The display panel according to claim 1, wherein the bonding region is further provided with an electrostatic lead configured to transmit static electricity on the cover plate layer to a ground pin in the composite circuit region.

13. The display panel according to claim 12, wherein the electrostatic lead comprises a first electrostatic lead disposed in the display substrate, the first electrostatic lead extends from the lead region to the composite circuit region, and an end of the first electrostatic lead is connected to the ground pin in the composite circuit region; a connection groove is provided on the first adhesive layer and the polarizing layer, the second adhesive layer fills the connection groove and is connected with the first electrostatic lead, and the static electricity of the cover plate layer is transmitted to the ground pin through the cover plate shield layer, the second adhesive layer and the first electrostatic lead.

14. The display panel according to claim 13, wherein, in a plane perpendicular to the display panel, the display substrate comprises a drive circuit layer disposed on a base substrate, a light emitting structure layer disposed on a side of the drive circuit layer away from the base substrate, an encapsulation structure layer disposed on a side of the light emitting structure layer away from the base substrate, and a touch structure layer disposed on a side of the encapsulation structure layer away from the base substrate, the first electrostatic lead is disposed in the touch structure layer, the first electrostatic lead and a touch lead in the touch structure layer are disposed on a same layer.

15. The display panel according to claim 12, wherein the electrostatic lead comprise a second electrostatic lead disposed on a side of the polarizer away from the display substrate, the second electrostatic lead extends from the lead region to the composite circuit region, an end of the second electrostatic lead is connected to a ground pin in the composite circuit region, and the static electricity of the cover plate layer is transmitted to the ground pin through the cover plate shield layer, the second adhesive layer and the second electrostatic lead.

16. (canceled)

17. The display panel according to claim 1, wherein the second functional layer comprises at least a third adhesive layer disposed on a backlight side surface of the display substrate, a reinforcing layer disposed on a side of the third adhesive layer away from the display substrate, and a spacer disposed on a side of the reinforcing layer away from the display substrate, a material of the reinforcing layer comprises stainless steel, and a material of the third adhesive layer comprises pressure sensitive adhesive.

18. The display panel according to claim 17, wherein the third adhesive layer is disposed in the lead region, the bending region and the composite circuit region, the reinforcing layer is disposed in the lead region and the composite circuit region, or the reinforcing layer is disposed in the lead region, the bending region and the composite circuit region.

19. The display panel according to claim 18, wherein the reinforcing layers of the lead region and the composite circuit region are provided with a plurality of first reinforcing grooves, and groove depths of the plurality of first reinforcing grooves gradually increase in a direction close to the bending region.

20. The display panel according to claim 19, wherein the reinforcing layers of the lead region and the composite circuit region comprise at least an equal groove depth region and a variable groove depth region, the equal groove depth region is located on a side of the variable groove depth region close to the bending region, groove depths of the plurality of first reinforcing grooves in the equal groove depth region are equal, and groove depths of the plurality of first reinforcing grooves in the variable groove depth region gradually increase along a direction close to the bending region.

21-22. (canceled)

23. The display panel according to claim 18, wherein the reinforcing layer of the bending region is provided with a plurality of second reinforcing grooves, groove depths of the plurality of second reinforcing grooves are equal to a thickness of the reinforcing layer.

24. (canceled)

25. The display panel according to claim 1, wherein the second functional layer comprises at least a conductive paste layer disposed on a backlight side surface of the display substrate, a reinforcing layer disposed on a side of the conductive paste layer away from the display substrate, and a spacer disposed on a side of the reinforcing layer away from the display substrate, a material of the reinforcing layer comprises stainless steel, and a material of the conductive paste layer comprises graphene or a graphene composite.

26-27. (canceled)

28. A preparation method of a display panel, the display panel comprising a display region and a bonding region located on a side of the display region, wherein the bonding region comprises a lead region, a bending region and a composite circuit region arranged sequentially in a direction away from the display region, the bending region is configured to flip the composite circuit region to a back of the display region by being bent; the preparation method comprising:
forming a first functional layer and a second functional layer on a light exit side surface and a backlight side surface of a display substrate, respectively; a first functional layer of the bonding region at least comprises a first adhesive layer, a polarizing layer disposed on a side of the first adhesive layer away from the display substrate, a second adhesive layer disposed on a side of the polarizing layer away from the display substrate, and a cover plate layer disposed on a side of the second adhesive layer away from the display substrate; the first adhesive layer and the polarizing layer are disposed in the lead region, the bending region and the composite circuit region, a side of the cover plate layer close to the display substrate is provided with a cover plate shield layer, and at least one of the display substrate, the first adhesive layer and the polarizing layer is provided with a bonding shield layer, a distance between an edge of a side of the bonding shield layer close to the display region and a boundary of the display region is less than a distance between an edge of a side of the cover plate shield layer close to the display region and the boundary of the display region, and the boundary of the display region is an edge of a side of the display region close to the bonding region.
